(19) United States
(12) Patent Application Publication
(10) Pub. No.: US 2014/0061753 A1
(43) Pub. Date: Mar. 6, 2014

(54) SEMICONDUCTOR DEVICE

(71) Applicant: KABUSHIKI KAISHA TOSHIBA, Minato-ku (JP)

(72) Inventor: Kenrou KIKUCHI, Mie-ken (JP)

(73) Assignee: KABUSHIKI KAISHA TOSHIBA, Minato-ku (JP)

(21) Appl. No.: 13/946,452

(22) Filed: Jul. 19, 2013

(30) Foreign Application Priority Data
Sep. 4, 2012 (JP) 2012-194266

(51) Int. Cl. H01L 29/788

(52) U.S. Cl. CPC H01L 29/788
USPC 257/315

(57) ABSTRACT

According to one embodiment, a semiconductor device includes a semiconductor substrate and a memory cell provided on the semiconductor substrate. The memory cell includes a first insulating film provided on the semiconductor substrate, a first conductive layer provided on the first insulating film, a first insulating layer provided on the first conductive layer, and a first silicide layer including a silicide provided on the first insulating layer to contact the first insulating layer.

### CROSS-REFERENCE TO RELATED APPLICATIONS

This application is based upon and claims the benefit of priority from Japanese Patent Application No. 2012-194266, filed on Sep. 4, 2012; the entire contents of which are incorporated herein by reference.

### FIELD

Embodiments described herein relate generally to a semiconductor device.

### BACKGROUND

Memory cells occupy the greater part of the chip surface area of a semiconductor device, e.g., flash memory. The shrinking of the semiconductor device is performed mainly for the region of the memory cells. However, as the shrinking of the memory cell, the coupling ratio decreases due to the effects of a depletion layer occurred in the control gate and the floating gate that include polysilicon.

### BRIEF DESCRIPTION OF THE DRAWINGS

FIG. 1A is a cross-sectional view showing an example of a cell region of a semiconductor device according to a first embodiment; FIG. 1B is a cross-sectional view showing an example of a peripheral circuit region thereof; and FIG. 1C is a cross-sectional view showing an example of a peripheral resistance element region thereof;

FIG. 2A is a cross-sectional view along line AA′ of FIG. 1A showing an example of the cell region of the semiconductor device according to the first embodiment; FIG. 2B is a cross-sectional view along line BB′ of FIG. 1B showing an example of the peripheral circuit region thereof; and FIG. 2C is a cross-sectional view along line CC′ of FIG. 1C showing an example of the peripheral resistance element region thereof;

FIG. 3A is a cross-sectional view of a process, showing an example of a method for manufacturing the cell region of the semiconductor device according to the first embodiment; FIG. 3B is a cross-sectional view of the process, showing an example of a method for manufacturing the peripheral circuit region; and FIG. 3C is a cross-sectional view of the process, showing an example of a method for manufacturing the peripheral resistance element region;

FIG. 4A is a cross-sectional view of a process, showing an example of a method for manufacturing the cell region of the semiconductor device according to the first embodiment; FIG. 4B is a cross-sectional view of the process, showing an example of a method for manufacturing the peripheral circuit region; and FIG. 4C is a cross-sectional view of the process, showing an example of a method for manufacturing the peripheral resistance element region;

FIG. 5A is a cross-sectional view of a process, showing an example of a method for manufacturing the cell region of the semiconductor device according to the first embodiment; FIG. 5B is a cross-sectional view of the process, showing an example of a method for manufacturing the peripheral circuit region; and FIG. 5C is a cross-sectional view of the process, showing an example of a method for manufacturing the peripheral resistance element region;

FIG. 6A is a cross-sectional view showing an example of a cell region of a semiconductor device according to a comparative example of the first embodiment; FIG. 6B is a cross-sectional view showing an example of a peripheral circuit region; and FIG. 6C is a cross-sectional view showing an example of a peripheral resistance element region;

FIG. 7A is a cross-sectional view of a process, showing an example of a method for manufacturing the cell region of the semiconductor device according to the comparative example of the first embodiment; FIG. 7B is a cross-sectional view of the process, showing an example of a method for manufacturing the peripheral circuit region; and FIG. 7C is a cross-sectional view of the process, showing an example of a method for manufacturing the peripheral resistance element region;

FIG. 8A is a cross-sectional view of a process, showing an example of the method for manufacturing the cell region of the semiconductor device according to the comparative example of the first embodiment; FIG. 8B is a cross-sectional view of the process, showing an example of the method for manufacturing the peripheral circuit region; and FIG. 8C is a cross-sectional view of the process, showing an example of the method for manufacturing the peripheral resistance element region;

FIG. 9 is a cross-sectional view showing an example of the cell region of the semiconductor device according to the comparative example of the first embodiment;

FIG. 10A is a cross-sectional view showing an example of a cell region of the semiconductor device according to a second embodiment; FIG. 10B is a cross-sectional view showing an example of a peripheral circuit region thereof; and FIG. 10C is a cross-sectional view showing an example of a peripheral resistance element region thereof;

FIG. 11A is a cross-sectional view of a process, showing an example of a method for manufacturing the cell region of the semiconductor device according to the second embodiment; FIG. 11B is a cross-sectional view of the process, showing an example of a method for manufacturing the peripheral circuit region; and FIG. 11C is a cross-sectional view of the process, showing an example of a method for manufacturing the peripheral resistance element region;

FIG. 12A is a cross-sectional view of a process, showing an example of a method for manufacturing the cell region of the semiconductor device according to the second embodiment; FIG. 12B is a cross-sectional view of the process, showing an example of a method for manufacturing the peripheral circuit region; and FIG. 12C is a cross-sectional view of the process, showing an example of a method for manufacturing the peripheral resistance element region;

FIG. 13A is a cross-sectional view of a process, showing an example of a method for manufacturing the cell region of the semiconductor device according to the second embodiment; FIG. 13B is a cross-sectional view of the process, showing an example of a method for manufacturing the peripheral circuit region; and FIG. 13C is a cross-sectional view of the process, showing an example of a method for manufacturing the peripheral resistance element region;

FIG. 14A is a cross-sectional view showing an example of a cell region of the semiconductor device according to a third embodiment; FIG. 14B is a cross-sectional view showing an example of a peripheral circuit region thereof; and FIG. 14C is a cross-sectional view showing an example of a peripheral resistance element region thereof;

FIG. 15A is a cross-sectional view of a process, showing an example of a method for manufacturing the cell region of the semiconductor device according to the third embodiment; FIG. 15B is a cross-sectional view of the process, showing an example of a method for manufacturing the peripheral circuit region; and FIG. 15C is a cross-sectional view of the process, showing an example of a method for manufacturing the peripheral resistance element region;

FIG. 16A is a cross-sectional view of a process, showing an example of a method for manufacturing the cell region of the semiconductor device according to the third embodiment; FIG. 16B is a cross-sectional view of the process, showing an example of a method for manufacturing the peripheral circuit region; and FIG. 16C is a cross-sectional view of the process, showing an example of a method for manufacturing the peripheral resistance element region;

FIG. 17A is a cross-sectional view showing an example of a cell region of the semiconductor device according to a fourth embodiment; FIG. 17B is a cross-sectional view showing an example of a peripheral circuit region thereof; and FIG. 17C is a cross-sectional view showing an example of a peripheral resistance element region thereof;

FIG. 18A is a cross-sectional view showing an example of a cell region of the semiconductor device according to a fifth embodiment; FIG. 18B is a cross-sectional view showing an example of a peripheral circuit region thereof; and FIG. 18C is a cross-sectional view showing an example of a peripheral resistance element region thereof;

FIG. 19A is a cross-sectional view of a process, showing an example of a method for manufacturing the cell region of the semiconductor device according to the fifth embodiment; FIG. 19B is a cross-sectional view of the process, showing an example of a method for manufacturing the peripheral circuit region; and FIG. 19C is a cross-sectional view of the process, showing an example of a method for manufacturing the peripheral resistance element region;

FIG. 20A is a cross-sectional view of a process, showing an example of a method for manufacturing the cell region of the semiconductor device according to the fifth embodiment; FIG. 20B is a cross-sectional view of the process, showing an example of a method for manufacturing the peripheral circuit region; and FIG. 20C is a cross-sectional view of the process, showing an example of a method for manufacturing the peripheral resistance element region; and

FIG. 21A is a cross-sectional view of a process, showing an example of a method for manufacturing the cell region of the semiconductor device according to the fifth embodiment; FIG. 21B is a cross-sectional view of the process, showing an example of a method for manufacturing the peripheral circuit region; and FIG. 21C is a cross-sectional view of the process, showing an example of a method for manufacturing the peripheral resistance element region.

### DETAILED DESCRIPTION

In general, according to one embodiment, a semiconductor device includes a semiconductor substrate and a memory cell provided on the semiconductor substrate. The memory cell includes a first insulating film provided on the semiconductor substrate, a first conductive layer provided on the first insulating film, a first insulating layer provided on the first conductive layer, and a first silicide layer including a silicide provided on the first insulating layer to contact the first insulating layer.

Embodiments of the invention will now be described with reference to the drawings.

### First Embodiment

First, a first embodiment will be described.

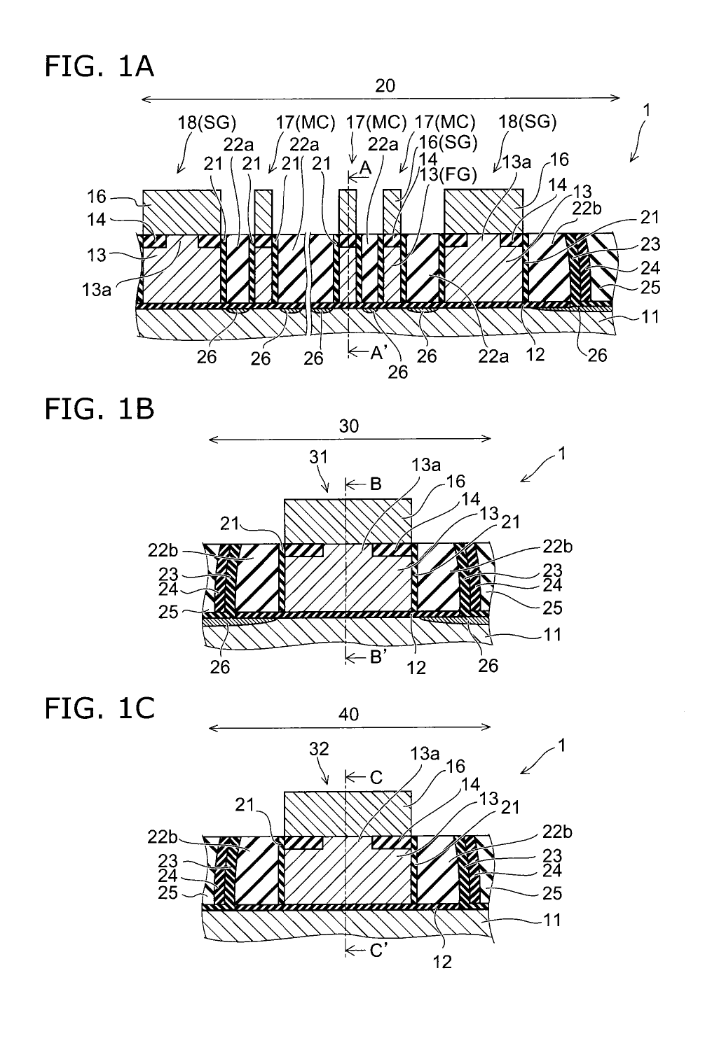

FIG. 1A is a cross-sectional view showing the cell region of a semiconductor device according to the first embodiment.

As shown in FIG. 1A, a semiconductor substrate 11, e.g., a silicon substrate, is provided in the semiconductor device 1 according to the embodiment. A cell region 20 is provided in the semiconductor substrate 11. Memory cells are provided on the semiconductor substrate 11 in the cell region 20. As described below, although the memory cells include a portion of the semiconductor substrate 11 in addition to components formed on the semiconductor substrate 11, the memory cells are referred to as being provided on the semiconductor substrate 11 in the specification for convenience. This is similar for the transistors described below.

An insulating film 12 (a first insulating film) is provided on the semiconductor substrate 11. The insulating film 12 includes, for example, silicon oxide. Multiple stacked bodies 17 and multiple stacked bodies 18 are provided on the insulating film 12 to extend in first direction in the upper surface of the insulating film 12. The multiple stacked bodies 17 are arranged periodically between the stacked bodies 18 in one other direction that is orthogonal to the first direction. The stacked bodies 17 may be used as, for example, memory cells MC. The stacked bodies 18 are separated from the stacked bodies 17 on the semiconductor substrate 11. The stacked bodies 18 may be used as, for example, selection gates SG. The insulating film 12 of the stacked body 17 may be used as a tunneling insulating film. The insulating film 12 of the stacked body 18 may be used as a gate insulating film.

The stacked body 17 and the stacked body 18 include a conductive layer 13 (a first conductive layer), an insulating layer 14 (a first insulating layer), and a silicide layer 16 (a first silicide layer). The conductive layer 13 is disposed on the insulating film 12. The conductive layer 13 includes, for example, polycrystalline silicon. The conductive layer 13 of the stacked body 17 may be used as, for example, a floating gate FG that is used as a charge storage layer. The insulating layer 14 is disposed on the conductive layer 13. The insulating layer 14 of the stacked body 17 may include, for example, an IPD film and may be used as an inter-electrode insulating layer.

The silicide layer 16 is disposed on the insulating layer 14. The silicide layer 16 is disposed to contact the insulating layer 14. The silicide layer 16 includes, for example, nickel silicide (NiSi). The silicide layer 16 of the stacked body 17 may be used as, for example, a control gate CG.

A through-portion 13a is provided in the insulating layer 14 of the stacked body 18 to pierce the insulating layer 14. The through-portion 13a includes, for example, polycrystalline silicon. The conductive layer 13 is connected to the silicide layer 16 by the through-portion 13a.

An insulating film 22a is provided between the stacked bodies 17, and between the stacked body 17 and the stacked body 18. Also, a sidewall insulating film 22b is provided on the side surface of the stacked body 18 on the side opposite to the insulating film 22a. The insulating film 22a and the sidewall insulating film 22b include, for example, silicon oxide. The upper ends of the insulating film 22a and the sidewall insulating film 22b are set to be higher than the lower surface of the insulating layer 14, e.g., at the same position as the upper surface of the insulating layer 14.

An insulating film 21 is provided between the insulating film 22a and the stacked body 17, between the insulating film 22a and the stacked body 18, and between the sidewall insulating film 22b and the stacked body 18. The insulating film 21 includes, for example, silicon oxide. A sidewall insulating film 23 is provided on the side surface of the sidewall insulating film 22b on the side opposite to the stacked body 18. The sidewall insulating film 23 includes, for example, silicon nitride. A sidewall insulating film 24 is provided on the side surface of the sidewall insulating film 23 on the side opposite to the sidewall insulating film 22b. The sidewall insulating film 24 includes, for example, silicon oxide.

An inter-layer insulating film 25 is provided on the side surface of the sidewall insulating film 24 on the side opposite to the sidewall insulating film 23. The inter-layer insulating film 25 includes, for example, silicon oxide. Also, the upper ends of the insulating film 21, the sidewall insulating film 23, the sidewall insulating film 24, and the inter-layer insulating film 25 are set to be higher than the lower surface of the insulating layer 14, e.g., at the same position as the upper surface of the insulating layer 14. An impurity layer 26 is formed in the semiconductor substrate 11 including the regions directly under the insulating film 22a and the sidewall insulating film 22b.

FIG. 1B is a cross-sectional view showing a peripheral circuit region of the semiconductor device according to the first embodiment.

As shown in FIG. 1B, the peripheral circuit region 30 also is provided in the semiconductor substrate 11 to be separated from the cell region 20. A transistor is provided on the semiconductor substrate 11 in the peripheral circuit region 30.

In the peripheral circuit region 30, the insulating film 12 (a third insulating film) is provided on the semiconductor substrate 11. A stacked body 31 is provided on the insulating film 12 to extend in the first direction in the upper surface of the insulating film 12. The stacked body 31 may be used as, for example, the gate of the transistor of the peripheral circuit.

The stacked body 31 includes the conductive layer 13 (a third conductive layer), the insulating layer 14 (a fourth insulating film), and the silicide layer 16 (a fourth silicide layer). The conductive layer 13 is disposed on the insulating film 12. The conductive layer 13 includes, for example, polysilicon. The insulating layer 14 is disposed on the conductive layer 13. The silicide layer 16 is disposed on the insulating layer 14. The silicide layer 16 is disposed to contact the insulating layer 14. The silicide layer 16 includes, for example, nickel silicide (NiSi). The through-portion 13a (a third through-portion) is provided in the insulating layer 14 to pierce the insulating layer 14. The through-portion 13a includes, for example, polycrystalline silicon. The conductive layer 13 is connected to the silicide layer 16 by the through-portion 13a.

The sidewall insulating film 22b is provided on the side surface of the stacked body 31. The sidewall insulating film 22b includes, for example, silicon oxide. The upper end of the sidewall insulating film 22b is set to be higher than the lower surface of the insulating layer 14, e.g., at the same position as the upper surface of the insulating layer 14.

The insulating film 21 is provided between the sidewall insulating film 22b and the stacked body 31. The insulating film 21 includes, for example, silicon oxide. The sidewall insulating film 23 is provided on the side surface of the sidewall insulating film 22b on the side opposite to the stacked body 31.

The sidewall insulating film 23 includes, for example, silicon nitride. The sidewall insulating film 24 is provided on the side surface of the sidewall insulating film 23 on the side opposite to the sidewall insulating film 22b. The sidewall insulating film 24 includes, for example, silicon oxide.

The inter-layer insulating film 25 is provided on the side surface of the sidewall insulating film 24 on the side opposite to the sidewall insulating film 23. The inter-layer insulating film 25 includes, for example, silicon oxide. Also, the upper ends of the insulating film 21, the sidewall insulating film 23, the sidewall insulating film 24, and the inter-layer insulating film 25 are set to be higher than the lower surface of the insulating layer 14, e.g., at the same position as the upper surface of the insulating layer 14. The impurity layer 26 is formed in the semiconductor substrate 11 including the region directly under the sidewall insulating film 22b.

FIG. 1C is a cross-sectional view showing a peripheral resistance element region of the semiconductor device according to the first embodiment.

As shown in FIG. 1C, the peripheral resistance element region 40 also is provided in the semiconductor substrate 11 to be separated from the cell region 20 and the peripheral circuit region 30. The resistance element is provided on the semiconductor substrate 11 in the peripheral resistance element region 40.

The insulating film 12 (a second insulating film) is provided on the semiconductor substrate 11 in the peripheral resistance element region 40. A stacked body 32 is provided on the insulating film 12 to extend in the first direction in the upper surface of the insulating film 12. The stacked body 32 may be used as the resistance element.

The stacked body 32 also includes the conductive layer 13 (a second conductive layer), the insulating layer 14 (second and third insulating layers), and the silicide layer 16 (second and third silicide layers). The conductive layer 13 is disposed on the insulating film 12. The conductive layer 13 includes, for example, polysilicon. The insulating layer 14 is disposed on the conductive layer 13. The silicide layer 16 is disposed on the insulating layer 14. The silicide layer 16 is disposed to contact the insulating layer 14. The silicide layer 16 includes, for example, nickel silicide (NiSi). The silicide layer 16 on the insulating layer 14 may be used as, for example, a terminal unit of the resistance element. The through-portion 13a (the first and second through-portions) is provided also in the insulating layer 14 of the stacked body 32 to pierce the insulating layer 14. The through-portion 13a includes, for example, polycrystalline silicon. The conductive layer 13 is connected to the silicide layer 16 by the through-portion 13a.

The sidewall insulating film 22b is provided on the side surface of the stacked body 32. The sidewall insulating film 22b includes, for example, silicon oxide. The upper end of the sidewall insulating film 22b is set to be higher than the lower surface of the insulating layer 14, e.g., at the same position as the upper surface of the insulating layer 14.

The insulating film 21 is provided between the sidewall insulating film 22b and the stacked body 32. The insulating film 21 includes, for example, silicon oxide. The sidewall insulating film 23 is provided on the side surface of the sidewall insulating film 22b on the side opposite to the stacked body 32. The sidewall insulating film 23 includes, for example, silicon nitride. The sidewall insulating film 24 is provided on the side surface of the sidewall insulating film 23 on the side opposite to the sidewall insulating film 22b. The sidewall insulating film 24 includes, for example, silicon oxide.

The inter-layer insulating film 25 is provided on the side surface of the sidewall insulating film 24 on the side opposite to the sidewall insulating film 23. The inter-layer insulating film 25 includes, for example, silicon oxide. The upper ends of the insulating film 21, the sidewall insulating film 23, the sidewall insulating film 24, and the inter-layer insulating film 25 also are set to be higher than the lower surface of the insulating layer 14, e.g., at the same position as the upper surface of the insulating layer 14.

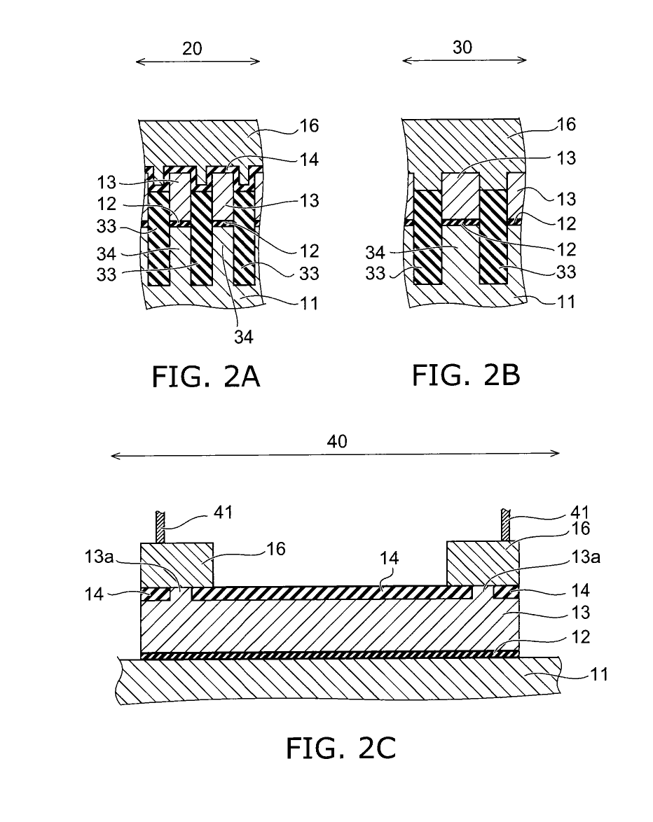

FIG. 2A is a cross-sectional view along line AA′ of FIG. 1A showing the cell region of the semiconductor device according to the first embodiment.

In the cell region 20 as shown in FIG. 2A, multiple element-separating layers 33 are provided in the upper portion of the semiconductor substrate 11 to extend in the one other direction that is orthogonal to the first direction. The element-separating layer 33 includes, for example, silicon oxide. The lower portion of the element-separating layer 33 is positioned lower than the upper surface of the semiconductor substrate 11; and the upper portion of the element-separating layer 33 is positioned higher than the upper surface of the semiconductor substrate 11. The portion of the semiconductor substrate 11 interposed between the lower portions of the element-separating layers 33 is called an active layer 34.

The insulating film 12 is disposed on the semiconductor substrate 11 between the element-separating layers 33. The upper surface of the insulating film 12 is positioned lower than the upper surface of the element-separating layer 33. The conductive layer 13 is disposed in the region directly above the insulating film 12 between the element-separating layers 33. The upper surface of the conductive layer 13 is positioned higher than the upper surface of the element-separating layer 33. The upper surface of the element-separating layer 33 is interposed between the side surfaces of the conductive layer 13 that are orthogonal to the first direction.

The insulating layer 14 is disposed to cover the upper surface of the element-separating layer 33, the upper surface of the conductive layer 13, and the portion of the side surface of the conductive layer 13 that is higher than the upper surface of the element-separating layer 33. The silicide layer 16 is disposed on the insulating layer 14.

FIG. 2B is a cross-sectional view along line BB′ of FIG. 1B showing the peripheral circuit region of the semiconductor device according to the first embodiment.

In the peripheral circuit region 30 as shown in FIG. 2B, the multiple element-separating layers 33 are provided in the upper portion of the semiconductor substrate 11 to extend in the one other direction that is orthogonal to the first direction. The element-separating layer 33 includes, for example, silicon oxide. The lower portion of the element-separating layer 33 is positioned lower than the upper surface of the semiconductor substrate 11; and the upper portion of the element-separating layer 33 is positioned higher than the upper surface of the semiconductor substrate 11. The portion of the semiconductor substrate 11 interposed between the lower portions of the element-separating layers 33 is called the active layer 34.

The insulating film 12 is disposed on the semiconductor substrate 11 between the element-separating layers 33. The upper surface of the insulating film 12 is positioned lower than the upper surface of the element-separating layer 33. The conductive layer 13 is disposed in the region directly above the insulating film 12 between the element-separating layers 33. The upper surface of the conductive layer 13 is positioned higher than the upper surface of the element-separating layer 33. The upper surface of the element-separating layer 33 is interposed between the side surfaces of the conductive layer 13 that are orthogonal to the first direction.

The silicide layer 16 is disposed to cover the upper surface of the element-separating layer 33, the upper surface of the conductive layer 13, and the portion of the side surface of the conductive layer 13 that is higher than the upper surface of the element-separating layer 33. The width of the element-separating layer 33 in the first direction in the peripheral circuit region 30 is wider than the width of the element-separating layer 33 in the first direction in the cell region 20. The width of the active layer 34 in the first direction in the peripheral circuit region 30 is wider than the width of the active layer 34 in the first direction in the cell region 20.

FIG. 2C is a cross-sectional view along line CC′ of FIG. 1C showing the peripheral resistance element region of the semiconductor device according to the first embodiment.

As shown in FIG. 2C, the insulating film 12 is disposed on the semiconductor substrate 11 in the peripheral resistance element region 40. The conductive layer 13 is disposed on the insulating film 12 to extend in the first direction. The insulating layer 14 is disposed on the conductive layer 13. The silicide layers 16 (the second and third silicide layers) are disposed on the insulating layer 14 at positions separated from each other at one side of the conductive layer 13 and at one other side of the conductive layer 13. The silicide layers 16 are separated from each other on the conductive layer 13. A contact 41 is connected to the upper surface of each of the silicide layers 16. Each of the silicide layers 16 on the insulating layer 14 may be used as, for example, a terminal unit of the resistance element.

The through-portion 13a (the first and second through-portions) is disposed in the insulating layer 14 between the conductive layer 13 and the silicide layer 16 to pierce the insulating layer 14. The conductive layer 13 is connected to the silicide layer 16 by the through-portion 13a.

Operations of the semiconductor device 1 according to the embodiment will now be described.

In the cell region 20, the multiple stacked bodies 18 and the multiple stacked bodies 17 are connected in series by sharing the impurity layers 26 as sources/drains. Thereby, a NAND string is formed. The stacked bodies 17 may be used as the memory cells MC; and the stacked bodies 18 may be used as the selection gates SG of the selection transistors. In other words, the stacked body 17 and the semiconductor substrate 11 around the region directly under the stacked body 17 are included in the memory cell MC; and the stacked body 18 and the semiconductor substrate 11 around the region directly under the stacked body 18 are included in the selection transistor. Then, a NAND string can be formed by connecting the memory cells MC and the selection transistors arranged in one column along one active layer 34 to each other in series by sharing the impurity layer 26 as a source/drain in each region between the memory cells MC and selection transistors that are adjacent to each other. One end of the NAND string is connected to a bit line. The other end of the NAND string is connected to a source line. A word line is connected to the silicide layer 16 on the stacked body 17. The semiconductor substrate 11 may be used as a channel.

The storage and discharge of the charge to and from the charge storage layer is controlled by the selection gates SG causing a current to flow in the semiconductor substrate 11 and by a voltage being applied to a word line that is selected. Thereby, the programming and erasing of the memory cells MC is performed.

In the peripheral circuit region 30, the stacked body 31 functions as, for example, a transistor including a selection gate that selects the bit line or the word line of the memory cell region 20. The stacked body 32 of the peripheral resistance element region 40 functions as, for example, a resistance element. The current value and the voltage value are controlled by including the terminal units disposed on the one end of the conductive layer 13 and the one other end of the conductive layer 13 of the stacked body 32 in the current path. In other words, the stacked body 32 can be used as a resistance element connected to two nodes of the current path by connecting the contact 41 provided at one end portion of the stacked body 32 to one of the nodes and by connecting the contact 41 provided at one other end portion of the stacked body 32 to the other node.

A method for manufacturing the semiconductor device 1 according to the embodiment will now be described.

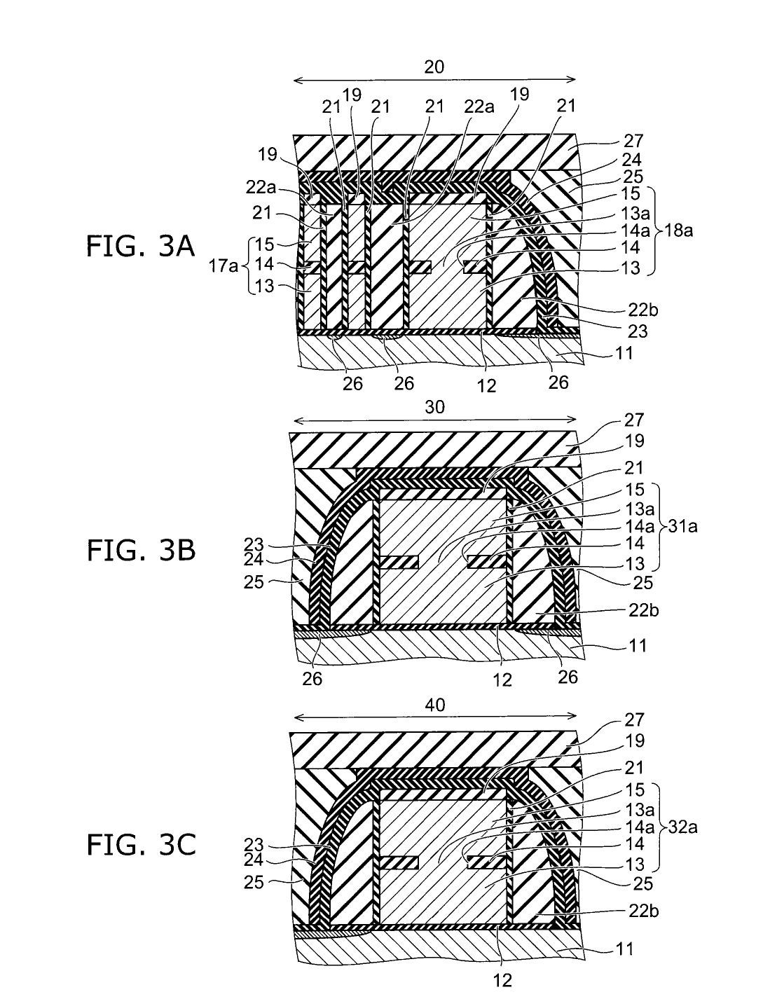

FIG. 3A is a cross-sectional view of a process, showing the method for manufacturing the cell region of the semiconductor device according to the first embodiment; FIG. 3B is a cross-sectional view of the process, showing the method for manufacturing the peripheral circuit region; and FIG. 3C is a cross-sectional view of the process, showing the method for manufacturing the peripheral resistance element region.

As shown in FIGS. 3A to 3C, the insulating film 12 is formed on the semiconductor substrate 11, e.g., a silicon substrate. The insulating film 12 includes, for example, silicon oxide. Then, the conductive layer 13 is formed on the insulating film 12. The conductive layer 13 includes, for example, polycrystalline silicon.

Then, the element-separating layer 33 (referring to FIG. 2A) is formed in the cell region 20 and the peripheral circuit region 30 to extend in the one other direction. To form the element-separating layer 33, first, a mask pattern having multiple openings that extend in the one other direction is formed on the conductive layer 13. Trenches are made by etching the upper portions of the conductive layer 13, the insulating film 12, and the semiconductor substrate 11 using the mask pattern. Then, the interior of the trenches is filled with an insulating material; and the upper surface of the insulating material that is filled is caused to be positioned lower than the upper surface of the conductive layer 13 and higher than the lower surface of the conductive layer 13. Then, the mask pattern is removed. Thus, the element-separating layer 33 (referring to FIG. 2A) is formed.

Continuing, the insulating layer 14 is formed on the conductive layer 13 in the cell region 20, the peripheral circuit region 30, and the peripheral resistance element region 40. An opening 14a is made in the portions of the insulating layer 14 where the stacked body 18 (referring to FIG. 1A), the stacked body 31 (referring to FIG. 1B), and the stacked body 32 (referring to FIG. 1C) are to be formed. The opening 14a is made in the portion of the insulating layer 14 where the terminal unit is to be formed.

Then, a conductive layer 15 is formed on the insulating layer 14. For example, the conductive layer 15 is formed by depositing polysilicon containing an impurity. At this time, the polysilicon fills the interior of the opening 14a to contact the conductive layer 13; and the conductive layer 13 and the conductive layer 15 are connected to each other. The portion of the conductive layer 13 filled into the interior of the opening 14a is called the through-portion 13a. Subsequently, a capping member 19 is formed on the conductive layer 15. The capping member 19 is formed to have a portion extending in the first direction in the upper surface of the conductive layer 15.

Continuing, etching of the conductive layer 15, the insulating layer 14, and the conductive layer 13 is performed using the capping member 19 as a mask. Thereby, a stacked body 17a, a stacked body 18a, a stacked body 31a, and a stacked body 32a are formed. The stacked body 17a, the stacked body 18a, the stacked body 31a, and the stacked body 32a include the conductive layer 13, the insulating layer 14, and the conductive layer 15. Then, an impurity is introduced to the semiconductor substrate 11 by, for example, ion implantation using the stacked body 17a, the stacked body 18a, and the stacked body 31a as a mask. Thereby, the impurity layer 26 is formed in the semiconductor substrate 11 between the regions directly under the stacked bodies 17a, the semiconductor substrate 11 between the region directly under the stacked body 17a and the region directly under the stacked body 18a, and in the semiconductor substrate 11 adjacent to the region directly under the stacked body 31a. In the peripheral resistance element region 40, the portion of the conductive layer 15 other than the portions that are separated from each other at the two sides are removed.

Then, the insulating film 21 is formed on the side surfaces of the stacked body 17a, the stacked body 18a, the stacked body 31a, and the stacked body 32a. Subsequently, the insulating film 22a is filled between the stacked bodies 17a, and between the stacked body 17a and the stacked body 18a.

Also, the sidewall insulating film 22b is formed on the side surface of the stacked body 18a on the side opposite to the stacked body 17a, on the side surface of the stacked body 31a, and on the side surface of the stacked body 32a.

Continuing, the sidewall insulating film 23 is formed to cover the capping member 19, the upper end of the insulating film 21, the upper end of the insulating film 22a, and the sidewall insulating film 22b. The sidewall insulating film 24 is formed on the sidewall insulating film 23. Then, the inter-layer insulating film 25 is formed on the sidewall insulating film 24 to cover the stacked body 17a, the stacked body 18a, the stacked body 31a, and the stacked body 32a. Subsequently, the inter-layer insulating film 25 is planarized until the sidewall insulating film 24 is exposed. Then, an inter-layer insulating film 27 is formed on the sidewall insulating film 24 and on the inter-layer insulating film 25.

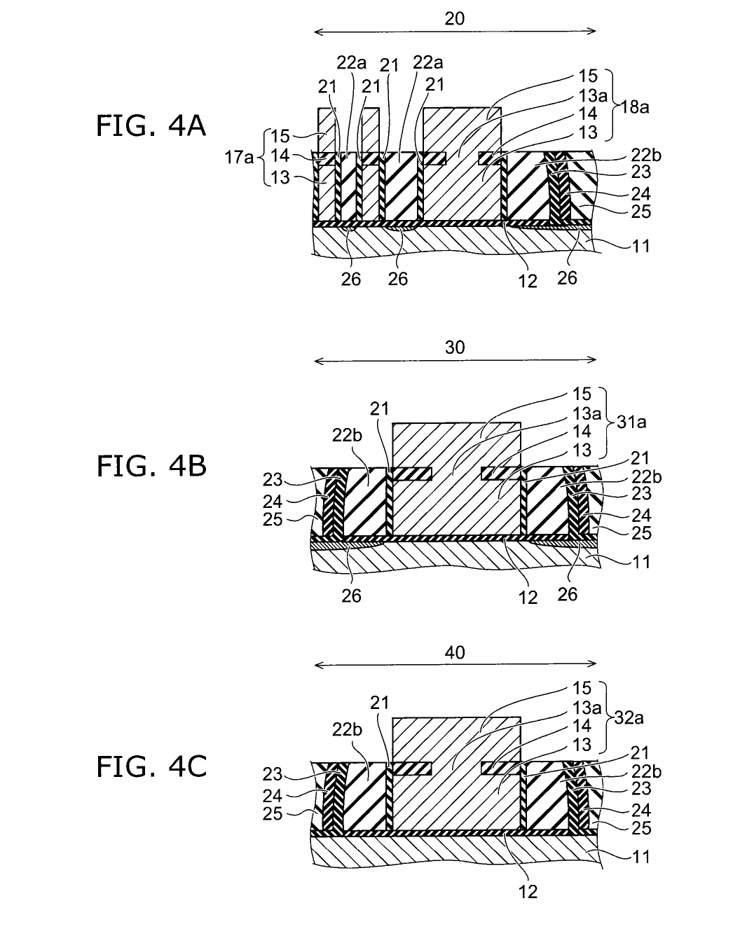

FIG. 4A is a cross-sectional view of a process, showing the method for manufacturing the cell region of the semiconductor device according to the first embodiment; FIG. 4B is a cross-sectional view of the process, showing the method for manufacturing the peripheral circuit region; and FIG. 4C is a cross-sectional view of the process, showing the method for manufacturing the peripheral resistance element region.

As shown in FIGS. 4A to 4C, by selectively etching-back the entire surface of the semiconductor substrate 11 from above in the cell region 20, the peripheral circuit region 30, and the peripheral resistance element region 40, the inter-layer insulating film 27 (referring to FIGS. 3A to 3C) is removed; and the insulating film 21, the insulating film 22a, the sidewall insulating film 22b, the sidewall insulating film 23, the sidewall insulating film 24, and the inter-layer insulating film 25 are removed until the upper ends of these insulating films are higher than the lower surface of the insulating layer 14, e.g., at the same position as the upper surface of the insulating layer 14. Thereby, the conductive layer 15 of the stacked body 17a, the stacked body 18a, the stacked body 31a, and the stacked body 32a is exposed above these insulating films. The reduced amount, i.e., the etching amount of these insulating films, is controlled by the etching time.

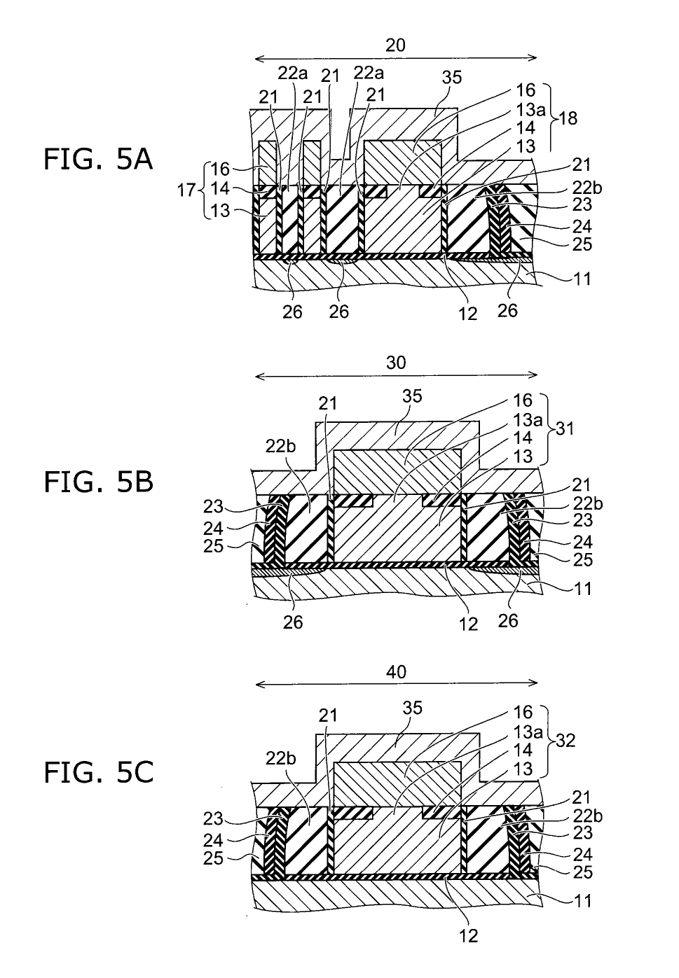

FIG. 5A is a cross-sectional view of a process, showing the method for manufacturing the cell region of the semiconductor device according to the first embodiment; FIG. 5B is a cross-sectional view of the process, showing the method for manufacturing the peripheral circuit region; and FIG. 5C is a cross-sectional view of the process, showing the method for manufacturing the peripheral resistance element region.

As shown in FIGS. 5A to 5C, a metal film 35 is formed on the semiconductor substrate 11 by depositing a metal material, e.g., nickel (Ni), by, for example, sputtering from above the semiconductor substrate 11. Then, the metal material, e.g., the nickel (Ni), of the metal film 35 is caused to react with the silicon of the exposed portion of the conductive layer 15 by heat treatment. Thereby, the conductive layer 15 changes into the silicide layer 16 including nickel silicide; and the stacked body 17a, the stacked body 18a, the stacked body 31a, and the stacked body 32a (referring to FIGS. 4A to 4C) become the stacked body 17, the stacked body 18, the stacked body 31, and the stacked body 32.

Then, the unreacted metal film 35 is removed by, for example, wet etching. Thus, the semiconductor device 1 such as that shown in FIGS. 1A to 1C is manufactured.

Thus, for example, the insulating film 12 is formed by the same processes in the memory cell region 20, the peripheral circuit region 30, and the peripheral resistance element region 40. Therefore, the thickness and composition of the insulating film 12 are equal between the regions. Also, the conductive layer 13 is formed by the same processes in each of the regions.

Therefore, the thickness and composition of the conductive layer 13 are equal between the regions. Further, the insulating layer 14 is formed by the same processes in each of the regions. Therefore, the thickness and composition of the insulating layer 14 are equal between the regions.

Effects of the embodiment will now be described.

In the semiconductor device 1 according to the embodiment, the silicide layer 16 is formed on the insulating layer 14 of the memory cell MC. Accordingly, the control gate CG does not include polysilicon and is a silicide layer. Accordingly, the occurrence of a depletion layer can be suppressed. Thereby, the decrease of the coupling ratio can be suppressed.

Although the control gate CG may be formed by patterning a metal film as a method for preventing the occurrence of the depletion layer of the control gate CG, in such a case, the selection of the material of the capping member 19 used to form the hard mask, the selection of the etching gas, and the removal of the deposits produced during the patterning are difficult. Further, the temperature of the subsequent heating processes is limited so as not to alter the metal film; and a drastic modification of the manufacturing processes becomes necessary. According to the embodiment, by siliciding, the occurrence of the depletion layer can be reduced without needing a drastic modification of the manufacturing processes.

Further, the cell region 20, the peripheral circuit region 30, and the peripheral resistance element region 40 can be manufactured simultaneously. In other words, a film of the same material can be formed simultaneously for the stacked body 17, the stacked body 18, the stacked body 31, and the stacked body 32. Thereby, the manufacturing processes can be reduced.

Although nickel silicide is formed using a material including nickel (Ni) as the metal film 35 and by causing the metal film 35 to react with the silicon included in the conductive film, this is not limited thereto. For example, the metal film 35 may include at least one metal selected from the group consisting of titanium (Ti), tungsten (W), and cobalt (Co) and may include other transition metals.

### Comparative Example

A comparative example of the first embodiment will now be described. The comparative example is an embodiment in which only a portion of the control gate and a portion of the conductive layer corresponding to the control gate are silicided.

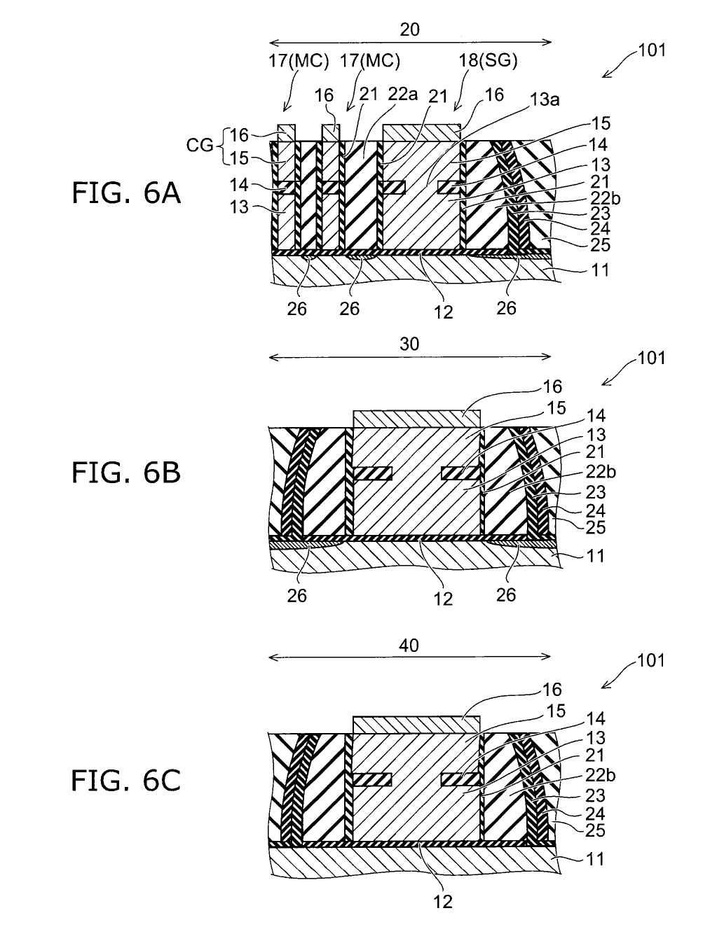

FIG. 6A is a cross-sectional view showing the cell region of the semiconductor device according to the comparative example of the first embodiment; FIG. 6B is a cross-sectional view showing the peripheral circuit region; and FIG. 6C is a cross-sectional view showing the peripheral resistance element region.

As shown in FIGS. 6A to 6C, the conductive layer 15 is provided on the insulating layer 14 in the cell region 20, the peripheral circuit region 30, and the peripheral resistance element region 40 of the semiconductor device 101 according to the comparative example. The silicide layer 16 is disposed on the conductive layer 15.

The control gate CG includes the conductive layer 15 and the silicide layer 16. Accordingly, in the comparative example, polysilicon is included in the control gate CG. The upper surfaces of the insulating film 21, the insulating film 22a, the sidewall insulating film 22b, the sidewall insulating film 23, the sidewall insulating film 24, and the inter-layer insulating film 25 are set to be at the same position as the upper surface of the conductive layer 15.

A method for manufacturing the semiconductor device 101 according to the comparative example will now be described.

First, similarly to the first embodiment described above, the processes shown in FIGS. 3A to 3C are implemented. A description is omitted for these processes.

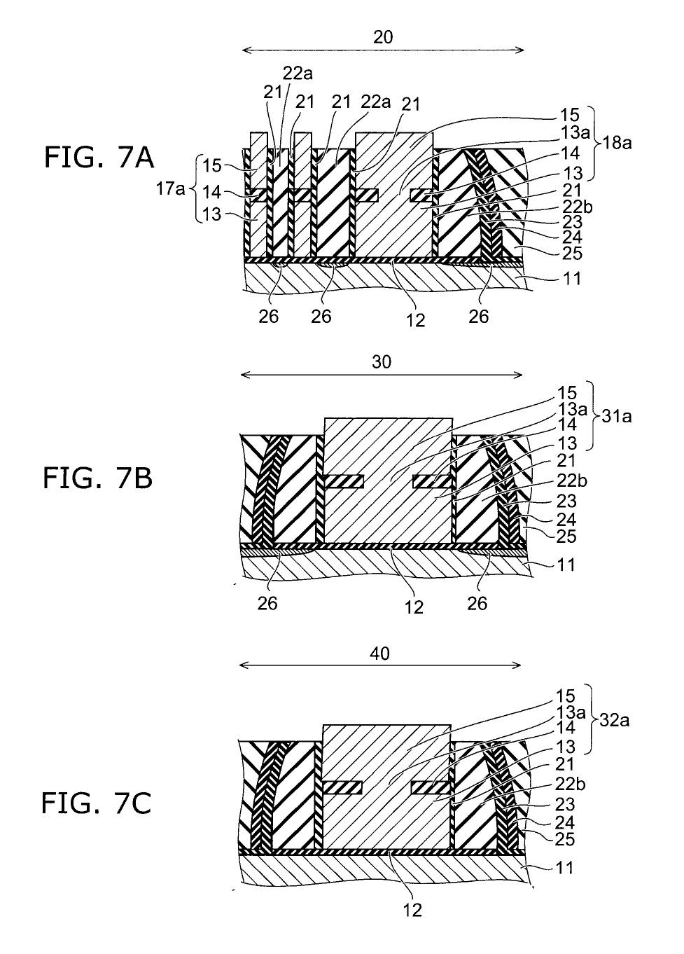

FIG. 7A is a cross-sectional view of a process, showing the method for manufacturing the cell region of the semiconductor device according to the comparative example of the first embodiment; FIG. 7B is a cross-sectional view of the process, showing the method for manufacturing the peripheral circuit region; and FIG. 7C is a cross-sectional view of the process, showing the method for manufacturing the peripheral resistance element region.

As shown in FIGS. 7A to 7C, by selectively etching-back the entire surface of the semiconductor substrate 11 from above in the cell region 20, the peripheral circuit region 30, and the peripheral resistance element region 40, the inter-layer insulating film 27 (referring to FIGS. 3A to 3C) is removed; and the insulating film 21, the insulating film 22a, the sidewall insulating film 22b, the sidewall insulating film 23, the sidewall insulating film 24, and the inter-layer insulating film 25 are removed until the upper ends of these insulating films are at a position that is lower than the upper surface of the conductive layer 15 and higher than the upper surface of the insulating layer 14. Thereby, the upper portion of the conductive layer 15 of the stacked body 17a, the stacked body 18a, the stacked body 31a, and the stacked body 32a is exposed above these insulating films.

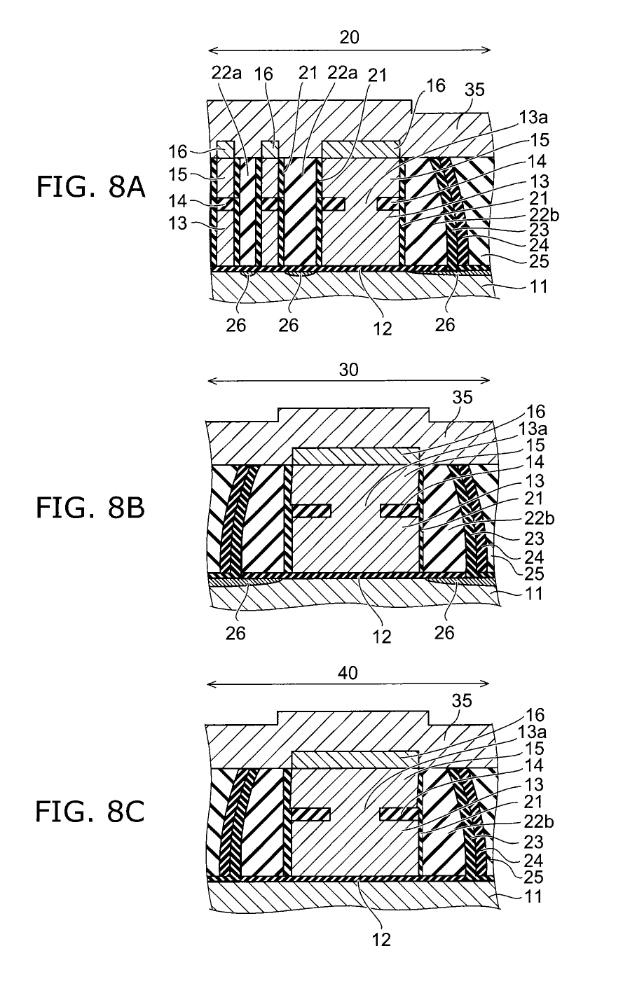

FIG. 8A is a cross-sectional view of a process, showing the method for manufacturing the cell region of the semiconductor device according to the comparative example of the first embodiment; FIG. 8B is a cross-sectional view of the process, showing the method for manufacturing the peripheral circuit region; and FIG. 8C is a cross-sectional view of the process, showing the method for manufacturing the peripheral resistance element region.

As shown in FIGS. 8A to 8C, the metal film 35 is formed on the semiconductor substrate 11 to cover the upper portion of the conductive layer 15 by depositing a metal material, e.g., nickel (Ni), from above the semiconductor substrate 11. Then, the metal material, e.g., the nickel (Ni), of the metal film 35 is caused to react with the silicon of the upper portion of the conductive layer 15 by heat treatment. Thereby, the upper portion of the conductive layer 15 is changed into the silicide layer 16 including nickel silicide.

Then, the unreacted metal film 35 is removed by, for example, wet etching. Thus, the semiconductor device 101 such as that shown in FIGS. 6A to 6C is manufactured.

In the comparative example, the control gate CG includes polysilicon. Accordingly, a depletion layer occurs in the control gate CG of the memory cell MC. The occurrence of the depletion layer will now be described.

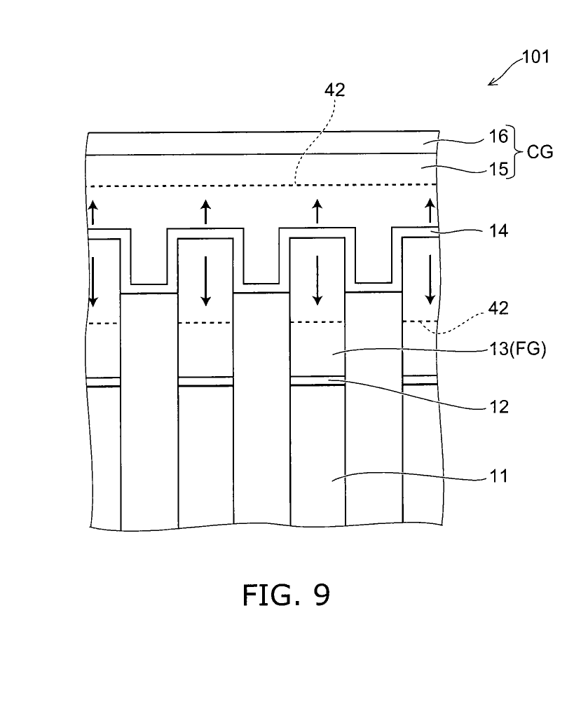

FIG. 9 is a cross-sectional view showing the cell region of the semiconductor device according to the comparative example of the first embodiment.

As shown in FIG. 9, a depletion layer 42 occurs in the polysilicon of the control gate CG of the semiconductor device 101 according to the comparative example from the interface with the insulating layer 14. Then, the depletion layer 42 spreads upward through the polysilicon. Thereby, the coupling ratio is reduced.

In the floating gate FG as well, the depletion layer 42 occurs in the polysilicon from the interface with the insulating layer 14 and spreads downward through the polysilicon. Thereby, the coupling ratio is reduced. Therefore, it is difficult to shrink the semiconductor device 101 because the programming/erasing characteristics undesirably degrade.

### Second Embodiment

A second embodiment will now be described. In the embodiment, a portion of the floating gate and a portion of the conductive layer corresponding to the floating gate are silicided in the cell region and the peripheral circuit region. In the peripheral resistance element region, a portion of the terminal unit is silicided.

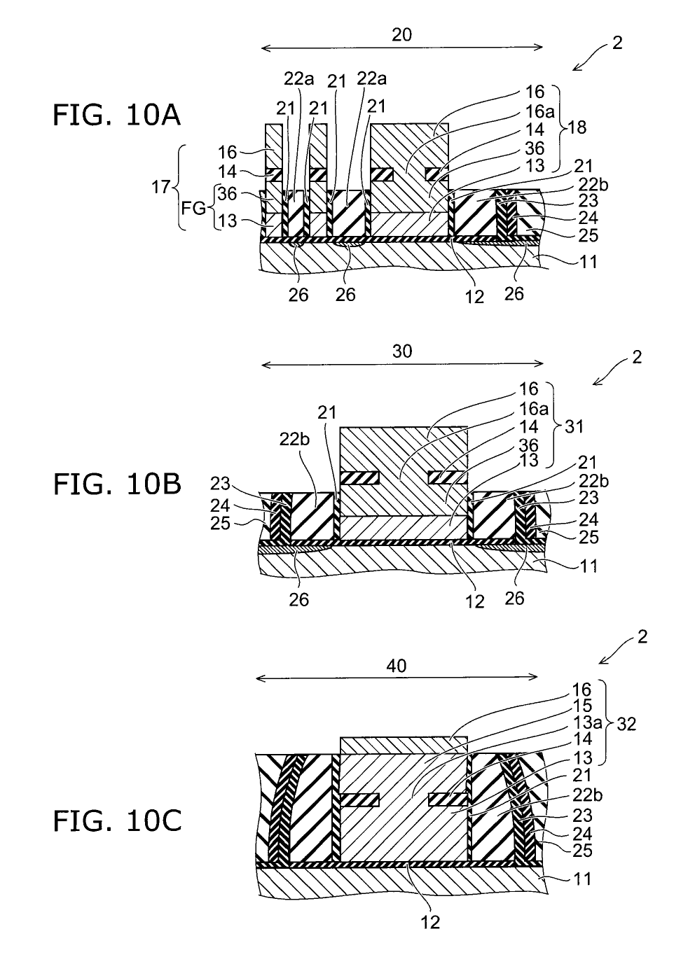

FIG. 10A is a cross-sectional view showing the cell region of the semiconductor device according to the second embodiment; FIG. 10B is a cross-sectional view showing the peripheral circuit region; and FIG. 10C is a cross-sectional view showing the peripheral resistance element region.

In the semiconductor device 2 of the embodiment as shown in FIGS. 10A to 10C, a silicide layer 36 (a fifth silicide layer) is provided between the conductive layer 13 and the insulating layer 14 in the cell region 20 and the peripheral circuit region 30. The silicide layer 36 is disposed to contact the lower surface of the insulating layer 14.

A through-portion 16a is provided in the insulating layer 14 of the stacked body 18 and the stacked body 31 to pierce the insulating layer 14. The through-portion 16a includes a silicide, e.g., nickel silicide. The upper ends of the insulating film 21, the insulating film 22a, the sidewall insulating film 22b, the sidewall insulating film 23, the sidewall insulating film 24, and the inter-layer insulating film 25 are set to be lower than the lower surface of the insulating layer 14 but higher than the upper surface of the conductive layer 13.

The conductive layer 15 is provided on the insulating layer 14 in the peripheral resistance element region 40. The silicide layer 16 is disposed on the conductive layer 15. The silicide layer 16 and the conductive layer 15 on the insulating layer 14 may be used as, for example, the terminal unit of the resistance element. The upper ends of the insulating film 21, the insulating film 22a, the sidewall insulating film 22b, the sidewall insulating film 23, the sidewall insulating film 24, and the inter-layer insulating film 25 are set to be higher than the upper surface of the insulating layer 14, e.g., at the same position as the upper surface of the conductive layer 15. Therefore, using the upper surface of the semiconductor substrate 11 as a reference, the lower surface of the silicon portion, i.e., the lower surface of the silicide layer 16, in the peripheral resistance element region 40 is positioned higher than the lower surface of the silicon portion, i.e., the lower surface of the silicide layer 36, in the cell region 20. Otherwise, the configuration and the operations of the embodiment are similar to those of the first embodiment described above.

A method for manufacturing the semiconductor device 2 according to the embodiment will now be described.

First, similarly to the first embodiment described above, the processes shown in FIGS. 3A to 3C are implemented. A description is omitted for these processes.

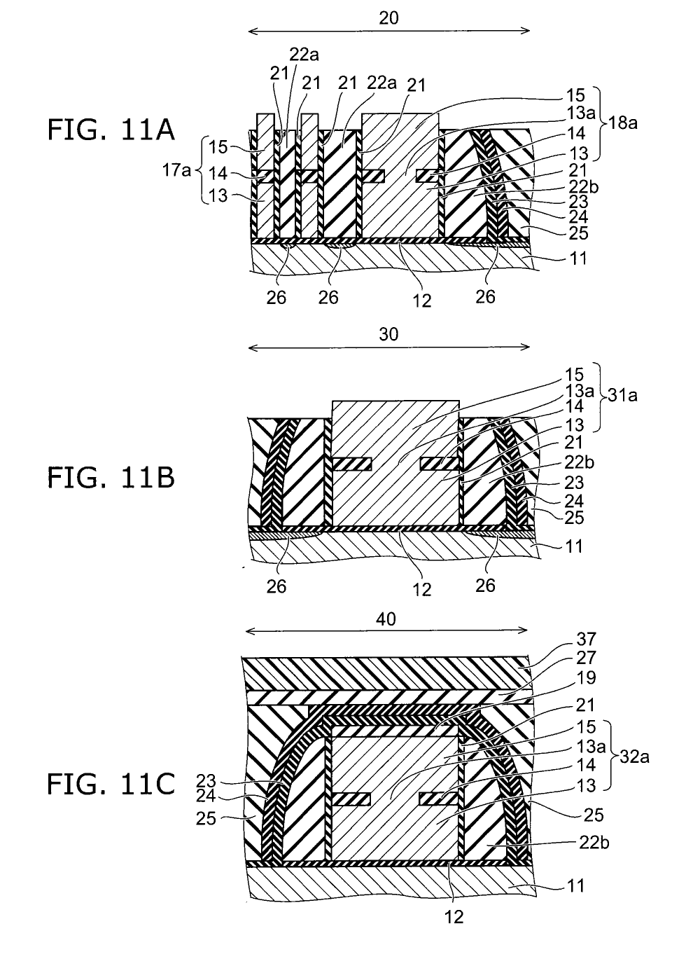

FIG. 11A is a cross-sectional view of a process, showing the method for manufacturing the cell region of the semiconductor device according to the second embodiment; FIG. 11B is a cross-sectional view of the process, showing the method for manufacturing the peripheral circuit region; and FIG. 11C is a cross-sectional view of the process, showing the method for manufacturing the peripheral resistance element region.

As shown in FIGS. 11A and 11B, by selectively etching-back the semiconductor substrate 11 from above in the cell region 20 and the peripheral circuit region 30, the inter-layer insulating film 27 (referring to FIGS. 3A and 3B) is removed; and the insulating film 21, the insulating film 22a, the sidewall insulating film 22b, the sidewall insulating film 23, the sidewall insulating film 24, and the inter-layer insulating film 25 are removed until the upper ends of these insulating films are at a position that is lower than the upper surface of the conductive layer 15 and higher than the upper surface of the insulating layer 14. Thereby, the upper portion of the conductive layer 15 of the stacked body 17a, the stacked body 18a, and the stacked body 31a is exposed above these insulating films.

On the other hand, in the peripheral resistance element region 40 as shown in FIG. 11C, etching-back of the peripheral resistance element region 40 is prevented by forming a resist 37 on the inter-layer insulating film 27. Subsequently, the resist 37 is removed.

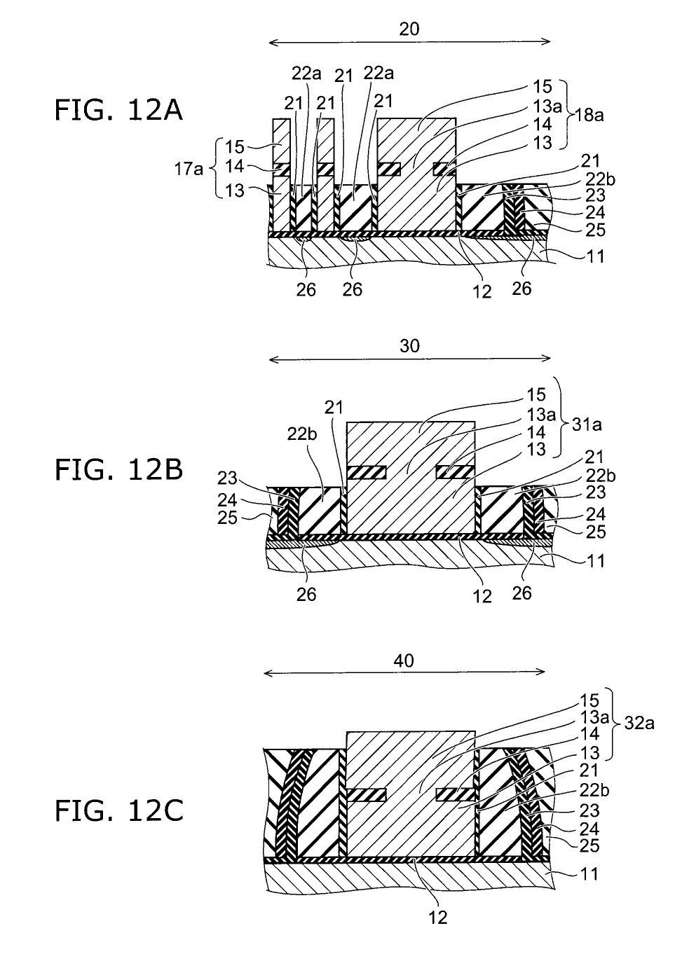

FIG. 12A is a cross-sectional view of a process, showing the method for manufacturing the cell region of the semiconductor device according to the second embodiment; FIG. 12B is a cross-sectional view of the process, showing the method for manufacturing the peripheral circuit region; and FIG. 12C is a cross-sectional view of the process, showing the method for manufacturing the peripheral resistance element region.

As shown in FIGS. 12A and 12B, by selectively etching-back the semiconductor substrate 11 from above in the cell region 20 and the peripheral circuit region 30, the insulating film 21, the insulating film 22a, the sidewall insulating film 22b, the sidewall insulating film 23, the sidewall insulating film 24, and the inter-layer insulating film 25 are removed until the upper ends of these insulating films are at a position that is higher than the lower surface of the conductive layer 13 and lower than the lower surface of the insulating layer 14. Half or more of the side surface of the conductive layer 13 is not exposed. Thereby, the conductive layer 15 and the upper portion of the conductive layer 13 of the stacked body 17a, the stacked body 18a, and the stacked body 31a are exposed above these insulating films.

As shown in FIG. 12C, by selectively etching-back the semiconductor substrate 11 from above in the peripheral resistance element region 40, the insulating film 21, the insulating film 22a, the sidewall insulating film 22b, the sidewall insulating film 23, the sidewall insulating film 24, and the inter-layer insulating film 25 are removed until the upper ends of these insulating films are at a position that is lower than the upper surface of the conductive layer 15 and higher than the upper surface of the insulating layer 14. Thereby, the upper portion of the conductive layer 15 of the stacked body 32a is exposed above these insulating films.

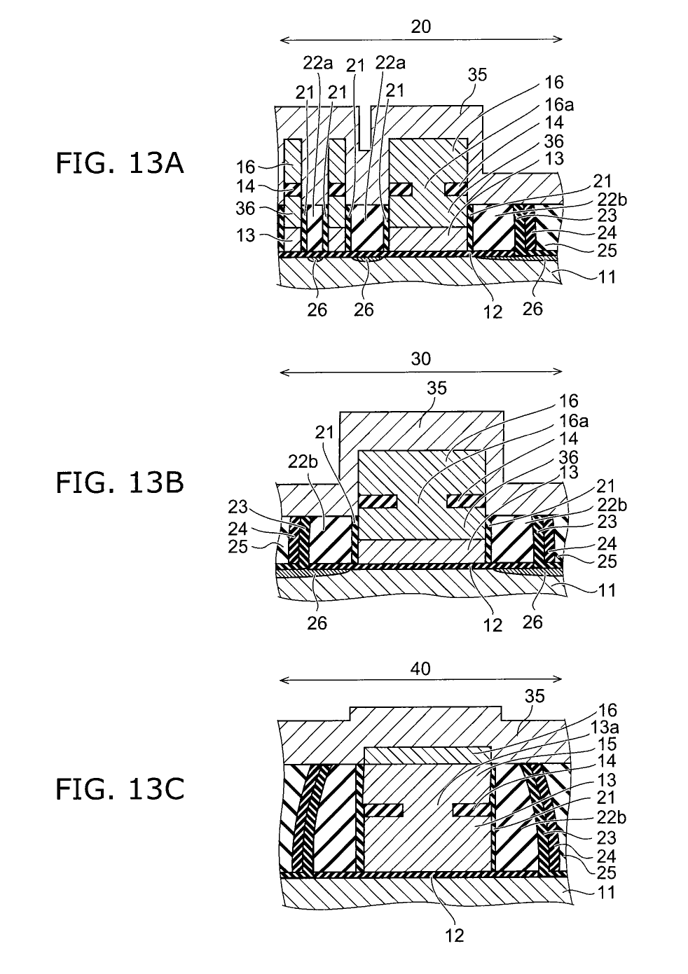

FIG. 13A is a cross-sectional view of a process, showing the method for manufacturing the cell region of the semiconductor device according to the second embodiment; FIG. 13B is a cross-sectional view of the process, showing the method for manufacturing the peripheral circuit region; and FIG. 13C is a cross-sectional view of the process, showing the method for manufacturing the peripheral resistance element region.

As shown in FIGS. 13A to 13C, the metal film 35 is formed on the semiconductor substrate 11 by depositing a metal material, e.g., nickel (Ni), from above the semiconductor substrate 11. Thereby, in the cell region 20 and the peripheral circuit region 30, the upper surface and side surface of the conductive layer 15 and the side surface of the upper portion of the conductive layer 13 are covered with the metal film 35. On the other hand, in the peripheral resistance element region 40, the upper portion of the conductive layer 15 is covered with the metal film 35.

Then, the metal material, e.g., the nickel (Ni), of the metal film 35 is caused to react with the silicon of the conductive layer 13 and the conductive layer 15 by heat treatment. Thereby, the conductive layer 15 and the upper portion of the conductive layer 13 are changed into the silicide layer 16 including nickel silicide in the cell region 20 and the peripheral circuit region 30. Also, in the peripheral resistance element region 40, the upper portion of the conductive layer 15 is changed into the silicide layer 16 including nickel silicide.

Then, the unreacted metal film 35 is removed by, for example, wet etching. Thus, the semiconductor device 2 such as that shown in FIGS. 10A to 10C is manufactured.

Effects of the embodiment will now be described.

In the semiconductor device 2 according to the embodiment, the silicide layer 36 is formed below the insulating layer 14 of the memory cell MC to contact the insulating layer 14. Accordingly, the upper portion of the floating gate FG becomes a silicide layer. Therefore, the occurrence of the depletion layer in the floating gate FG can be suppressed. Thereby, the decrease of the coupling ratio can be suppressed.

The floating gate FG may be formed by patterning a metal film as a method for preventing the occurrence of the depletion layer of the floating gate FG. However, in the case where the semiconductor device is flash memory, it is necessary to form an IPD film on the floating gate FG. There are cases where the metal film included in the floating gate FG cannot withstand the high-temperature oxidation atmosphere for forming the IPD film; and the manufacturing processes are limited. However, in the embodiment, the manufacturing processes are not limited compared to the case where the floating gate FG is formed by patterning the metal film because the floating gate FG is formed by siliciding.

In the peripheral resistance element, the resistance value is not changed from the resistance value of the conductive layer 13 because the conductive layer 13 is not silicided. Otherwise, the effects of the embodiment are similar to those of the first embodiment described above.

### Third Embodiment

A third embodiment will now be described. In the embodiment, the entire control gate, the entire floating gate, and the entire conductive layer corresponding to the control gate and the floating gate are silicided in the cell region and the peripheral circuit region. In the peripheral resistance element region, a portion of the terminal unit is silicided.

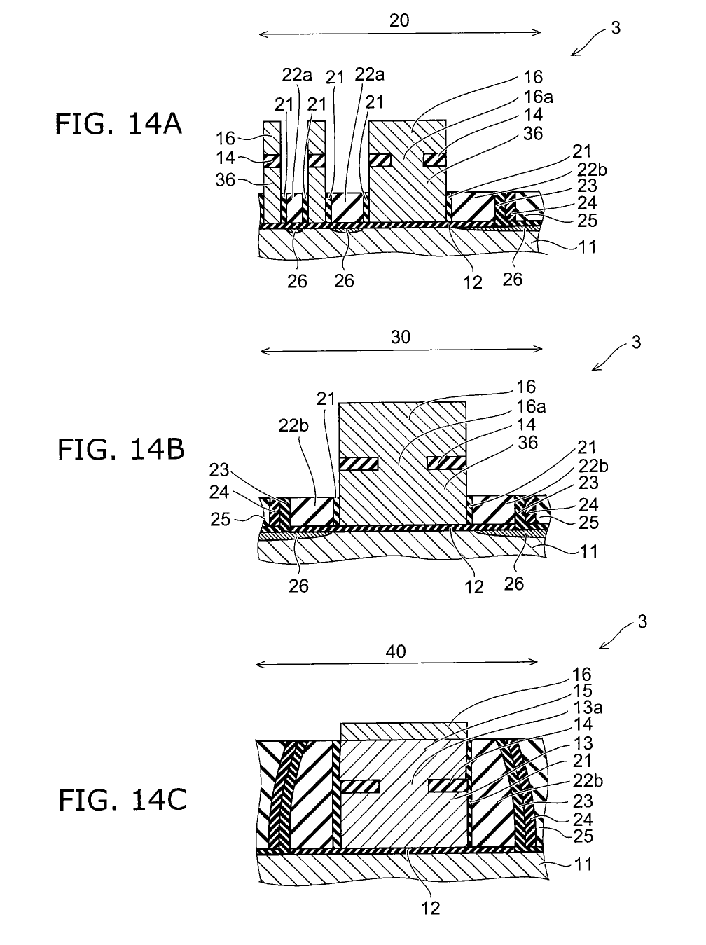

FIG. 14A is a cross-sectional view showing the cell region of the semiconductor device according to the third embodiment; FIG. 14B is a cross-sectional view showing the peripheral circuit region; and FIG. 14C is a cross-sectional view showing the peripheral resistance element region.

In the semiconductor device 3 of the embodiment as shown in FIGS. 14A to 14C, the silicide layer 36 is provided between the insulating film 12 and the insulating layer 14 in the cell region 20 and the peripheral circuit region 30. The silicide layer 36 is disposed to contact the insulating film 12 and the insulating layer 14. The upper ends of the insulating film 21, the insulating film 22a, the sidewall insulating film 22b, the sidewall insulating film 23, the sidewall insulating film 24, and the inter-layer insulating film 25 are set to be lower than the lower surface of the insulating layer 14 but higher than the upper surface of the conductive layer 13, and are set to be lower than those of the second embodiment described above.

In the peripheral resistance element region 40, the conductive layer 15 is provided on the insulating layer 14. The silicide layer 16 is disposed on the conductive layer 15. The upper ends of the insulating film 21, the insulating film 22a, the sidewall insulating film 22b, the sidewall insulating film 23, the sidewall insulating film 24, and the inter-layer insulating film 25 are set to be higher than the upper surface of the insulating layer 14, e.g., at the same position as the upper surface of the conductive layer 15.

A method for manufacturing the semiconductor device 3 according to the embodiment will now be described.

First, similarly to the first embodiment described above, the processes shown in FIGS. 3A to 3C are implemented. Then, similarly to the second embodiment described above, the processes shown in FIGS. 11A to 11C are implemented. A description is omitted for these processes.

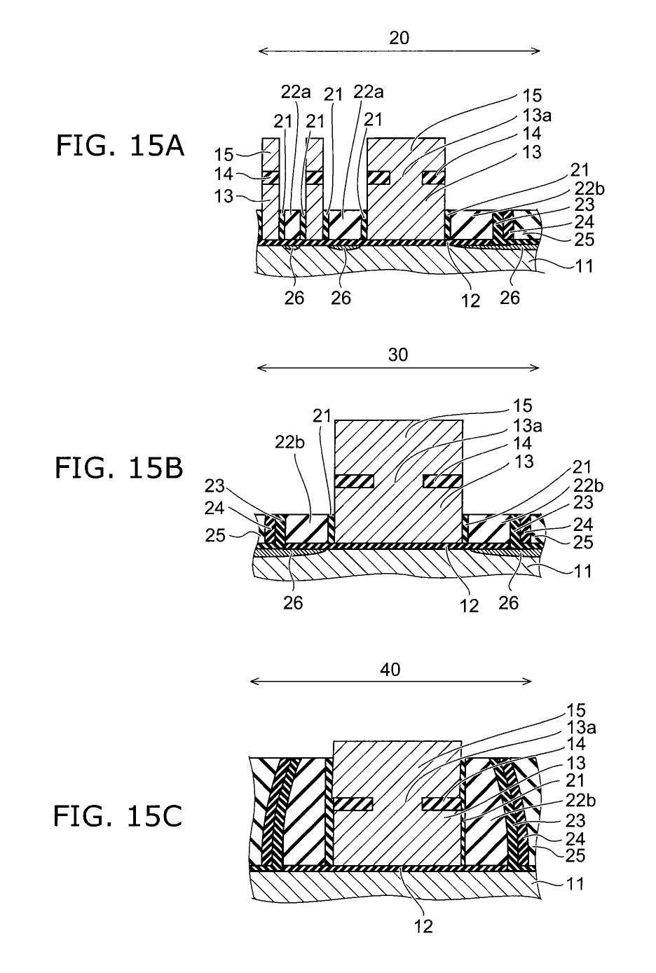

FIG. 15A is a cross-sectional view of a process, showing the method for manufacturing the cell region of the semiconductor device according to the third embodiment; FIG. 15B is a cross-sectional view of the process, showing the method for manufacturing the peripheral circuit region; and FIG. 15C is a cross-sectional view of the process, showing the method for manufacturing the peripheral resistance element region.

As shown in FIGS. 15A and 15B, by selectively etching-back the semiconductor substrate 11 from above in the cell region 20 and the peripheral circuit region 30, the insulating film 21, the insulating film 22a, the sidewall insulating film 22b, the sidewall insulating film 23, the sidewall insulating film 24, and the inter-layer insulating film 25 are removed until the upper ends of these insulating films are at a position that is higher than the lower surface of the conductive layer 13 and lower than the lower surface of the insulating layer 14. Half or more of the side surface of the conductive layer 13 is exposed. Thereby, the conductive layer 15 and the upper portion of the conductive layer 13 of the stacked body 17a, the stacked body 18a, and the stacked body 31a are exposed above these insulating films.

As shown in FIG. 15C, by selectively etching-back the semiconductor substrate 11 from above in the peripheral resistance element region 40, the insulating film 21, the insulating film 22a, the sidewall insulating film 22b, the sidewall insulating film 23, the sidewall insulating film 24, and the inter-layer insulating film 25 are removed until the upper ends of these insulating films are at a position that is lower than the upper surface of the conductive layer 15 and higher than the upper surface of the insulating layer 14. Thereby, the upper portion of the conductive layer 15 of the stacked body 32a is exposed above these insulating films.

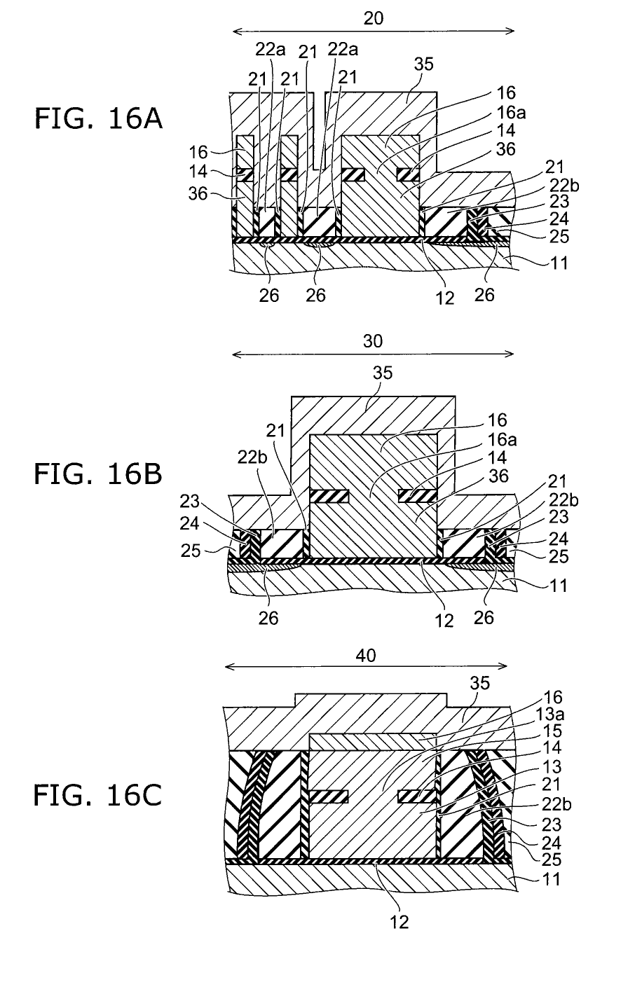

FIG. 16A is a cross-sectional view of a process, showing the method for manufacturing the cell region of the semiconductor device according to the third embodiment; FIG. 16B is a cross-sectional view of the process, showing the method for manufacturing the peripheral circuit region; and FIG. 16C is a cross-sectional view of the process, showing the method for manufacturing the peripheral resistance element region.

As shown in FIGS. 16A to 16C, the metal film 35 is formed on the semiconductor substrate 11 by depositing a metal material, e.g., nickel (Ni), from above the semiconductor substrate 11. Thereby, in the cell region 20 and the peripheral circuit region 30, the upper surface and side surface of the conductive layer 15 and the side surface of the upper portion of the conductive layer 13 are covered with the metal film 35. On the other hand, in the peripheral resistance element region 40, the upper portion of the conductive layer 15 is covered with the metal film 35.

Then, the metal material, e.g., the nickel (Ni), of the metal film 35 is caused to react with the silicon of the conductive layer 13 and the conductive layer 15 by heat treatment. Thereby, in the cell region 20 and the peripheral circuit region 30, the conductive layer 13 and the conductive layer 15 are changed into the silicide layer 16 including nickel silicide. In the peripheral resistance element region 40, the upper portion of the conductive layer 15 is changed into the silicide layer 16 including nickel silicide.

Then, the unreacted metal film 35 is removed by, for example, wet etching. Thus, the semiconductor device 3 such as that shown in FIGS. 14A to 14C is manufactured.

According to the embodiment, the occurrence of the depletion layer of the floating gate FG can be suppressed more than in the second embodiment described above. Otherwise, the configuration, the operations, and the effects of the embodiment are similar to those of the first embodiment described above.

### Fourth Embodiment

A fourth embodiment will now be described. In the embodiment, the entire control gate and the entire floating gate are silicided in the cell region. A portion of the conductive layer corresponding to the control gate is silicided in the peripheral circuit region; and a portion of the terminal unit is silicided in the peripheral resistance element region.

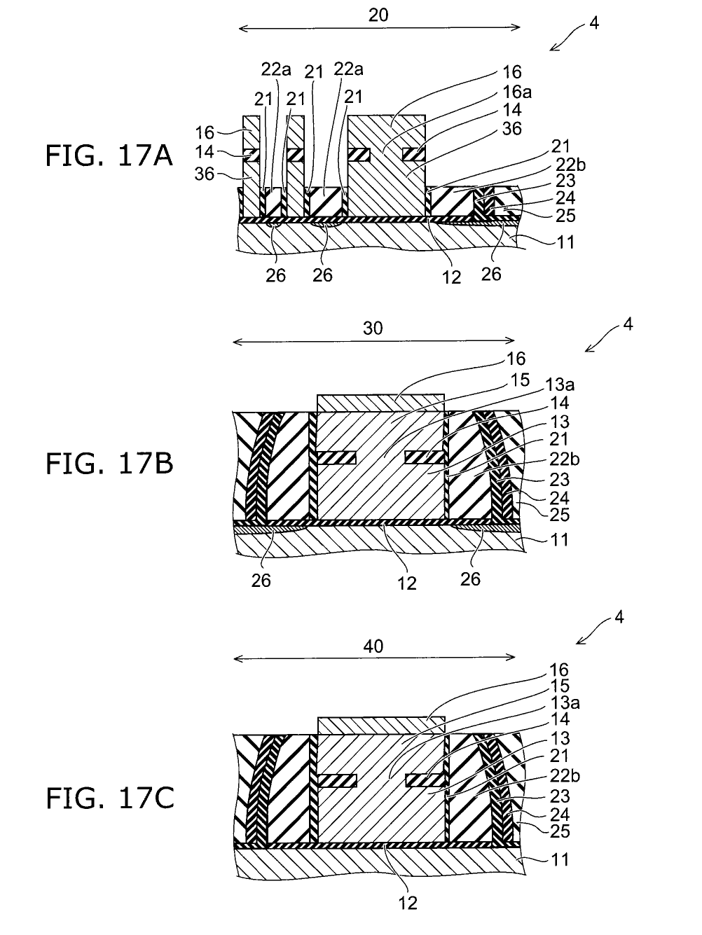

FIG. 17A is a cross-sectional view showing the cell region of the semiconductor device according to the fourth embodiment; FIG. 17B is a cross-sectional view showing the peripheral circuit region; and FIG. 17C is a cross-sectional view showing the peripheral resistance element region.

In the semiconductor device 4 of the embodiment as shown in FIG. 17A, the silicide layer 36 is provided between the insulating film 12 and the insulating layer 14 in the cell region 20. The silicide layer 36 is disposed to contact the insulating film 12 and the insulating layer 14. The upper ends of the insulating film 21, the insulating film 22a, the sidewall insulating film 22b, the sidewall insulating film 23, the sidewall insulating film 24, and the inter-layer insulating film 25 are set to be lower than the lower surface of the insulating layer 14 but higher than the upper surface of the insulating film 12.

The conductive layer 15 is provided on the insulating layer 14 in the peripheral circuit region 30 and the peripheral resistance element region 40. The silicide layer 16 is disposed on the conductive layer 15. The upper ends of the insulating film 21, the insulating film 22a, the sidewall insulating film 22b, the sidewall insulating film 23, the sidewall insulating film 24, and the inter-layer insulating film 25 are set to be higher than the upper surface of the insulating layer 14, e.g., at the same position as the upper surface of the conductive layer 15.

A method for manufacturing the semiconductor device 4 according to the embodiment will now be described.

In the cell region 20 and the peripheral resistance element region 40, the semiconductor device 4 according to the embodiment can be manufactured similarly to the third embodiment described above by implementing the processes shown in FIGS. 15A and 15C and FIGS. 16A and 16C. In the peripheral circuit region 30, the semiconductor device 4 can be manufactured similarly to the comparative example described above by implementing the processes shown in FIG. 7B and FIG. 8B.

Effects of the embodiment will now be described.

In the peripheral circuit region 30 of the semiconductor device 4 according to the embodiment, the silicide layer 16 is formed only at the upper portion of the conductive layer 15. Accordingly, in the case where the conductive layer 15 is caused to react with the metal film 35, the metal material included in the metal film 35 is not excessively supplied to the conductive layer 15. Therefore, excessive metal material does not coalesce and form defects in the conductive layer 15 by not reacting with the silicon of the conductive layer 15. Moreover, excessive metal material does not form voids inside the conductive layer 15 by assimilating the silicon of the conductive layer 15. Therefore, the semiconductor device 4 can be downscaled. Otherwise, the configuration, the operations, and the effects of the embodiment are similar to those of the first embodiment described above.

### Fifth Embodiment

A fifth embodiment will now be described. In the embodiment, a gap is made between the memory cells and at the side surfaces of the selection gate.

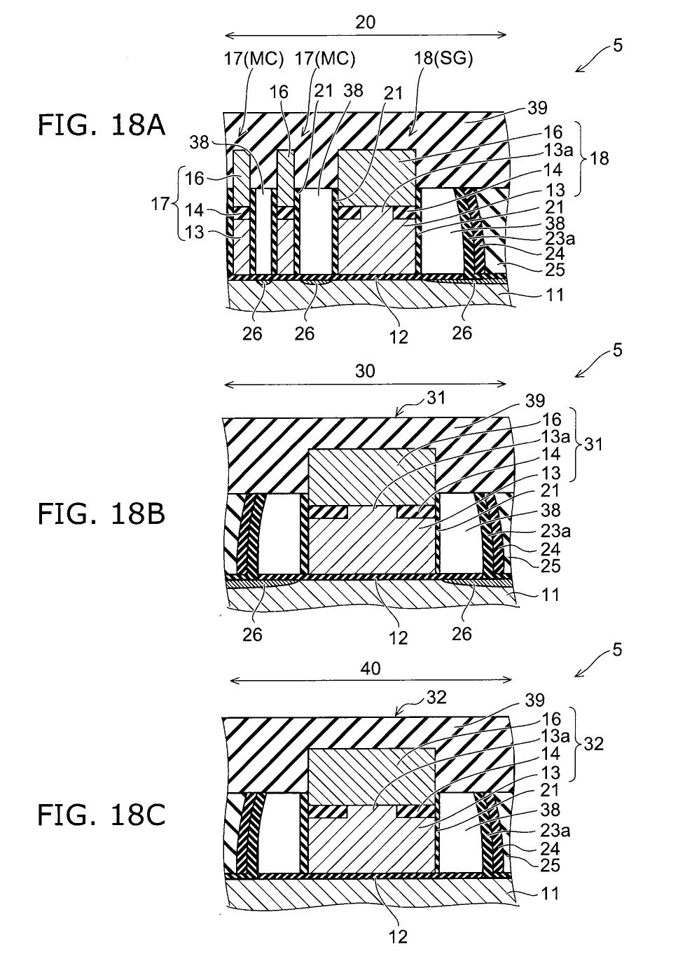

FIG. 18A is a cross-sectional view showing the cell region of the semiconductor device according to the fifth embodiment; FIG. 18B is a cross-sectional view showing the peripheral circuit region; and FIG. 18C is a cross-sectional view showing the peripheral resistance element region.

In the semiconductor device 5 according to the embodiment as shown in FIG. 18A, the side surfaces of the stacked body 17 and the stacked body 18 are covered with the insulating film 21. The insulating film 21 includes, for example, silicon oxide. A gap 38 is made between the stacked bodies 17 and between the stacked body 17 and the stacked body 18. Also, the gap 38 is made at the side surface side of the stacked body 18 on the side opposite to the stacked body 17. A sidewall insulating film 23a is provided with the gap 38 interposed at the side surface side of the stacked body 18 on the side opposite to the stacked body 17. The sidewall insulating film 23a includes, for example, silicon oxide.

The sidewall insulating film 24 is provided on the side surface of the sidewall insulating film 23a on the side opposite to the gap 38. The sidewall insulating film 24 includes, for example, silicon oxide. The inter-layer insulating film 25 is provided on the side surface of the sidewall insulating film 24 on the side opposite to the sidewall insulating film 23a. The inter-layer insulating film 25 includes, for example, silicon oxide. The upper ends of the insulating film 21, the sidewall insulating film 23a, the sidewall insulating film 24, and the inter-layer insulating film 25 are set to be higher than the upper surface of the insulating layer 14 and lower than the upper surface of the silicide layer 16. An insulating film 39 is provided to cover the upper portions of the stacked body 17 and the stacked body 18, the gap 38, and the upper ends of the insulating film 21, the sidewall insulating film 23a, the sidewall insulating film 24, and the inter-layer insulating film 25. The impurity layer 26 is formed in the semiconductor substrate 11 including the region directly under the gap 38.

FIG. 18B is a cross-sectional view showing the peripheral circuit region of the semiconductor device according to the fifth embodiment; and FIG. 18C is a cross-sectional view showing the peripheral resistance element region of the semiconductor device according to the fifth embodiment.

As shown in FIGS. 18B and 18C, the side surfaces of the stacked body 31 and the stacked body 32 are covered with the insulating film 21. The gap 38 is provided at the side surface sides of the stacked body 31 and the stacked body 32. The sidewall insulating film 23a is provided with the gap 38 interposed at the side surface sides of the stacked body 31 and the stacked body 32. The sidewall insulating film 23a includes, for example, silicon oxide.

The sidewall insulating film 24 is provided on the side surface of the sidewall insulating film 23a on the side opposite to the gap 38. The inter-layer insulating film 25 is provided on the side surface of the sidewall insulating film 24 on the side opposite to the sidewall insulating film 23a. The upper ends of the insulating film 21, the sidewall insulating film 23a, the sidewall insulating film 24, and the inter-layer insulating film 25 are set to be higher than the upper surface of the insulating layer 14 and lower than the upper surface of the silicide layer 16. The insulating film 39 is provided to cover the upper portions of the stacked body 31 and the stacked body 32, the gap 38, and the upper ends of the insulating film 21, the sidewall insulating film 23a, the sidewall insulating film 24, and the inter-layer insulating film 25. The impurity layer 26 is formed in the semiconductor substrate 11 including the region directly under the gap 38.

A method for manufacturing the semiconductor device 5 according to the embodiment will now be described.

First, similarly to the first embodiment described above, the processes shown in FIGS. 3A to 3C are implemented. A description is omitted for these processes.

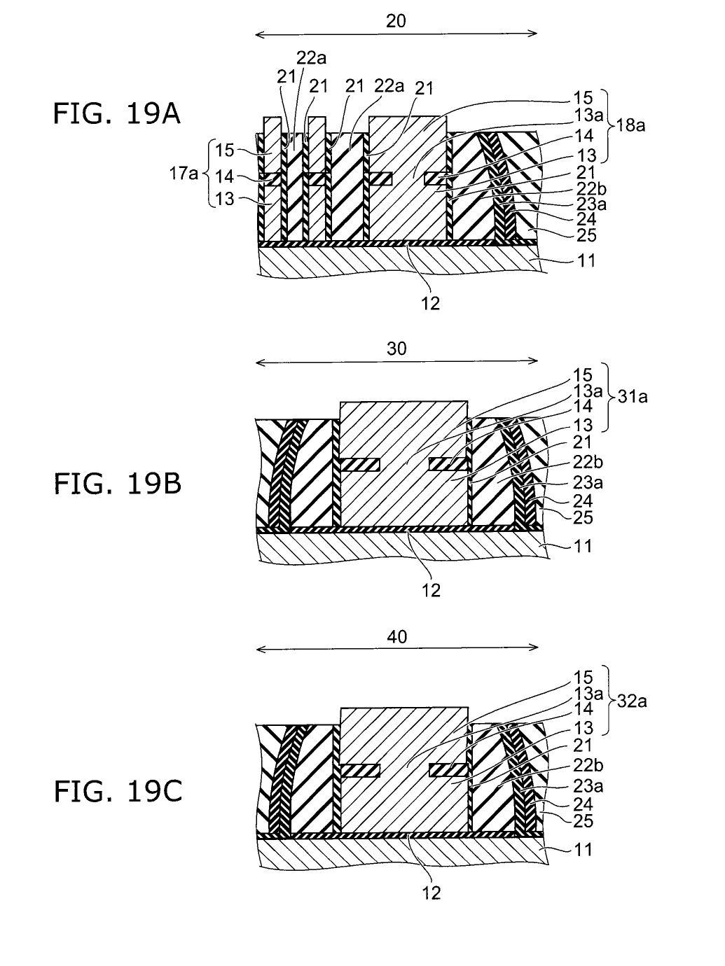

FIG. 19A is a cross-sectional view of a process, showing the method for manufacturing the cell region of the semiconductor device according to the fifth embodiment; FIG. 19B is a cross-sectional view of the process, showing the method for manufacturing the peripheral circuit region; and FIG. 19C is a cross-sectional view of the process, showing the method for manufacturing the peripheral resistance element region.

As shown in FIGS. 19A to 19C, by selectively etching-back the entire surface of the semiconductor substrate 11 from above in the cell region 20, the peripheral circuit region 30, and the peripheral resistance element region 40, the insulating film 21, the insulating film 22a, the sidewall insulating film 22b, the sidewall insulating film 23a, the sidewall insulating film 24, and the inter-layer insulating film 25 are removed until the upper ends of these insulating films are at a position that is lower than the upper surface of the conductive layer 15 and higher than the upper surface of the insulating layer 14. Thereby, the upper portion of the conductive layer 15 of the stacked body 17a, the stacked body 18a, the stacked body 31a, and the stacked body 32a is exposed above these insulating films. In the embodiment, the insulating film 22a and the sidewall insulating film 22b include silicon nitride.

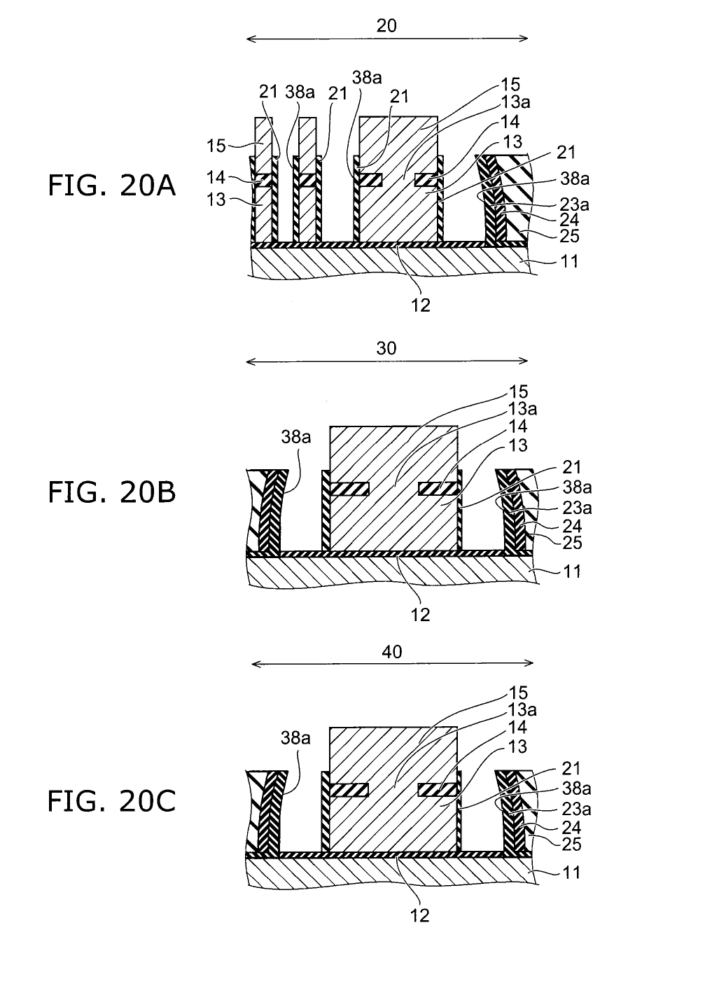

FIG. 20A is a cross-sectional view of a process, showing the method for manufacturing the cell region of the semiconductor device according to the fifth embodiment; FIG. 20B is a cross-sectional view of the process, showing the method for manufacturing the peripheral circuit region; and FIG. 20C is a cross-sectional view of the process, showing the method for manufacturing the peripheral resistance element region.

As shown in FIGS. 20A to 20C, the insulating film 22a and the sidewall insulating film 22b that include silicon nitride are selectively removed by phosphoric acid treatment at a high temperature. Thereby, a trench 38a is made.

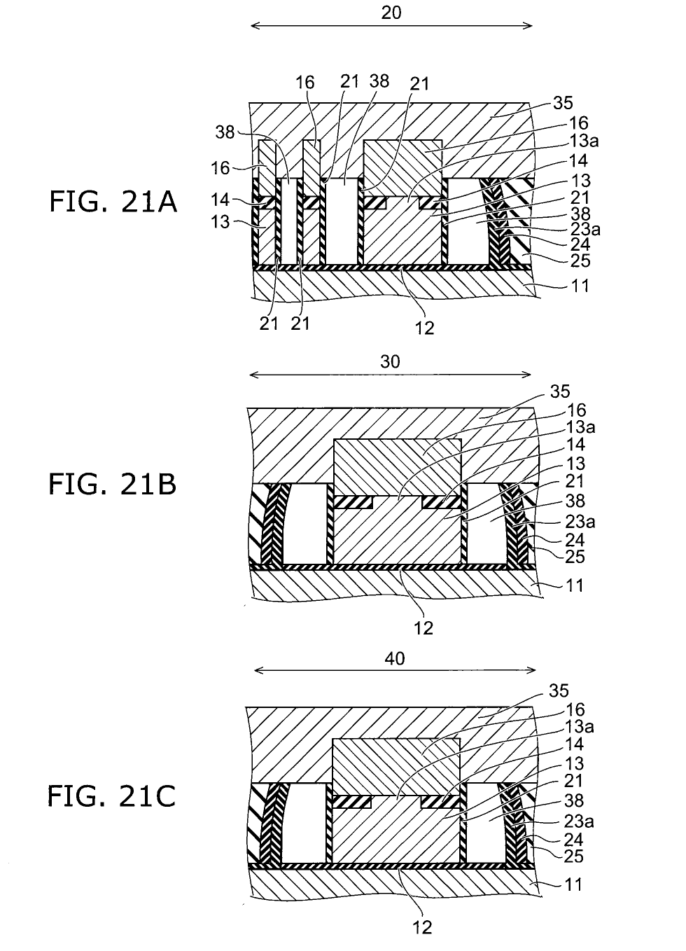

FIG. 21A is a cross-sectional view of a process, showing the method for manufacturing the cell region of the semiconductor device according to the fifth embodiment; FIG. 21B is a cross-sectional view of the process, showing the method for manufacturing the peripheral circuit region; and FIG. 21C is a cross-sectional view of the process, showing the method for manufacturing the peripheral resistance element region.

As shown in FIGS. 21A to 21C, the metal film 35 is formed on the semiconductor substrate 11 to cover the conductive layer 15 of the stacked body 17a, the stacked body 18a, the stacked body 31a, and the stacked body 32a by depositing a metal material, e.g., nickel (Ni), from above the semiconductor substrate 11. At this time, the insulating film 21 suppresses the filling of the trench 38a with the metal film 35.

Then, the metal material, e.g., the nickel (Ni), of the metal film 35 is caused to react with the silicon of the conductive layer 15 by heat treatment. Thereby, the conductive layer 15 changes into the silicide layer 16 including nickel silicide; and the stacked body 17a, the stacked body 18a, the stacked body 31a, and the stacked body 32a become the stacked body 17, the stacked body 18, the stacked body 31, and the stacked body 32.

Then, the unreacted metal film 35 is removed by, for example, wet etching. Subsequently, the insulating film 39 is formed on the semiconductor substrate 11 to cover the silicide layer 16 of the stacked body 17, the stacked body 18, the stacked body 31, and the stacked body 32 by depositing an insulating material, e.g., silicon oxide, from above the semiconductor substrate 11. At this time, the insulating film is formed at conditions to have poor step coverage. Thereby, the insulating film 39 is formed to cover the trench 38a without filling the trench 38a. Therefore, the gap 38 is made on the side surfaces of the stacked body 17, the stacked body 18, the stacked body 31, and the stacked body 32.

Thus, the semiconductor device 5 such as that shown in FIGS. 18A to 18C is manufactured.

Effects of the embodiment will now be described.

The gap 38 is made between the memory cells MC of the semiconductor device 1 of the embodiment. The coupling ratio increases because the parasitic capacitance between the memory cells MC decreases. Thereby, the semiconductor device 5 can be downscaled. Otherwise, the configuration, the operations, and the effects of the embodiment are similar to those of the first embodiment described above.

The combinations of the cell region 20, the peripheral circuit region 30, and the peripheral resistance element region 40 that are illustrated in each of the embodiments are not limited thereto. The cell region 20, the peripheral circuit region 30, and the peripheral resistance element region 40 of each of the embodiments may be combined with each other. For example, the semiconductor device may have a combination of the cell region 20 and the peripheral circuit region 30 of the first embodiment and the peripheral resistance element region 40 of the second embodiment.

Further, the gap 38 of the fifth embodiment may be made on the side surfaces of the stacked body 17, the stacked body 18, the stacked body 31, and the stacked body 32 of the second to fourth embodiments.

According to the embodiments described above, a semiconductor device that can be downscaled can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a semiconductor substrate; and
a memory cell provided on the semiconductor substrate, the memory cell including:
a first insulating film provided on the semiconductor substrate;
a first conductive layer provided on the first insulating film;
a first insulating layer provided on the first conductive layer; and
a first silicide layer including a silicide provided on the first insulating layer to contact the first insulating layer.

2. The device according to claim 1, further comprising a resistance element provided on the semiconductor substrate to be separated from the memory cell,
the resistance element including:
a second insulating film provided on the semiconductor substrate;
a second conductive layer provided on the second insulating film;
a second silicide layer including a silicide provided on the second conductive layer; and
a third silicide layer including a silicide provided on the second conductive layer to be isolated from the second silicide layer.

3. The device according to claim 2, wherein the resistance element further includes:
a second insulating layer provided between the second silicide layer and the second conductive layer;
a first through-portion piercing the second insulating layer to connect the second silicide layer to the second conductive layer;
a third insulating layer provided between the third silicide layer and the second conductive layer; and
a second through-portion piercing the third insulating layer to connect the third silicide layer to the second conductive layer.

4. The device according to claim 1, further comprising a transistor provided in the semiconductor substrate to be separated from the memory cell,
the transistor including:
a third insulating film provided on the semiconductor substrate;
a third conductive layer provided on the third insulating film;
a fourth insulating layer provided on the third conductive layer;
a fourth silicide layer including a silicide provided on the fourth insulating layer to contact the fourth insulating layer; and
a third through-portion piercing the fourth insulating layer to connect the fourth silicide layer to the third conductive layer.

5. The device according to claim 4, wherein
the memory cell is a portion of a NAND string, and
the transistor is configured to select a bit line or a word line connected to the NAND string.

6. The device according to claim 2, further comprising a transistor provided in the semiconductor substrate to be separated from the memory cell and the resistance element,
the transistor including:
a third insulating film provided on the semiconductor substrate;
a third conductive layer provided on the third insulating film;
a fourth insulating layer provided on the third conductive layer;
a fourth silicide layer including a silicide provided on the fourth insulating layer to contact the fourth insulating layer; and
a third through-portion piercing the fourth insulating layer to connect the fourth silicide layer to the third conductive layer.

7. The device according to claim 1, wherein the first conductive layer includes a silicide and is provided to contact the first insulating film and the first insulating layer.

8. The device according to claim 1, wherein the memory cell further includes a fifth silicide layer provided between the first conductive layer and the first insulating layer to contact the first insulating layer.

9. The device according to claim 8, further comprising a resistance element provided on the semiconductor substrate to be separated from the memory cell,
the resistance element including:
a second insulating film provided on the semiconductor substrate;
a second conductive layer provided on the second insulating film;
a second silicide layer including a silicide provided on the second conductive layer; and
a third silicide layer including a silicide provided on the second conductive layer to be isolated from the second silicide layer,
wherein a lower surface of the second silicide layer and a lower surface of the third silicide layer are positioned higher than a lower surface of the fifth silicide layer.

10. A semiconductor device, comprising:
a semiconductor substrate;
a memory cell provided on the semiconductor substrate;
a resistance element provided on the semiconductor substrate to be separated from the memory cell; and
a transistor provided on the semiconductor substrate to be separated from the memory cell and the resistance element,
the memory cell including:
a first insulating film provided on the semiconductor substrate;
a first conductive layer provided on the first insulating film;
a first insulating layer provided on the first conductive layer; and
a first silicide layer including a silicide provided on the first insulating layer to contact the first insulating layer,
the resistance element including:
a second insulating film provided on the semiconductor substrate;
a second conductive layer provided on the second insulating film;
a second silicide layer including a silicide provided on the second conductive layer;
a third silicide layer including a silicide provided on the second conductive layer to be isolated from the second silicide layer;
a second insulating layer provided between the second silicide layer and the second conductive layer;
a first through-portion piercing the second insulating layer to connect the second silicide layer to the second conductive layer;
a third insulating layer provided between the third silicide layer and the second conductive layer; and
a second through-portion piercing the third insulating layer to connect the third silicide layer to the second conductive layer,
the transistor including:
a third insulating film provided on the semiconductor substrate;
a third conductive layer provided on the third insulating film;
a fourth insulating layer provided on the third conductive layer;
a fourth silicide layer including a silicide provided on the fourth insulating layer to contact the fourth insulating layer; and
a third through-portion piercing the fourth insulating layer to connect the fourth silicide layer to the third conductive layer.

11. The device according to claim 10, wherein a lower surface of the second silicide layer and a lower surface of the third silicide layer are positioned higher than a lower surface of the first silicide layer.

12. The device according to claim 10, wherein a thickness of the first insulating film, a thickness of the second insulating film, and a thickness of the third insulating film are equal to each other.

13. The device according to claim 10, wherein a thickness of the first conductive layer, a thickness of the second conductive layer, and a thickness of the third conductive layer are equal to each other.

14. The device according to claim 10, wherein a thickness of the first insulating layer, a thickness of the second insulating layer, a thickness of the third insulating layer, and a thickness of the fourth insulating layer are equal to each other.

15. The device according to claim 10, wherein
the resistance element further includes a first sidewall insulating film, the first sidewall insulating film is provided on a side surface of the second conductive layer via a first gap, and
the transistor further includes a second sidewall insulating film, the second sidewall insulating film is provided on a side surface of the third conductive layer via a second gap.

16. The device according to claim 15, wherein an upper surface of the first sidewall insulating film and an upper surface of the second sidewall insulating film are equal to each other.
